(19) United States
(12) Patent Application Publication
(10) Pub. No.: US 2025/0051913 A1
(43) Pub. Date: Feb. 13, 2025

(54) CHEMICAL VAPOR DEPOSITION DEVICE WITH ADHERENCE DISRUPTION FEATURE AND METHODS OF USING THE SAME

(71) Applicants: VitriVax, Inc., Boulder, CO (US); The Regents of the University of Colorado, a body corporate, Denver, CO (US)

(72) Inventor: Hans Heinrich Funke, Boulder, CO (US)

(21) Appl. No.: 18/801,284

(22) Filed: Aug. 12, 2024

Related U.S. Application Data
(63) Continuation of application No. PCT/US2023/063738, filed on Mar. 3, 2023.
(60) Provisional application No. 63/336,863, filed on Apr. 29, 2022.
(60) Provisional application No. 63/330,166, filed on Apr. 12, 2022.
(60) Provisional application No. 63/316,947, filed on Mar. 4, 2022.

(51) Int. Cl. C23C 16/455; C23C 16/44; C23C 16/442

(52) U.S. Cl. CPC C23C 16/45544; C23C 16/4407; C23C 16/442

(57) ABSTRACT

Embodiments disclosed herein relate to a modified reactor system for creating coated particles of thermostable agents having reduced loss and improved coating uniformity due to avoidance of adherence of the particles to the reactor or to other particles. In certain embodiments, a reactor system includes a reactor vessel configured to receive particles of thermostable agents, and one or more agitating appendages or devices, including at least one of ultrasonic agitator, mechanical impactor, and low-frequency vibrator either directly connected or in fluid communication with the reactor system for sonicating, impacting, or vibrating a reactor vessel during the particle coating process. In some embodiments, the reactor system includes a gas phase dosing system configured to introduce alternating pulses of chemically gas phase materials into the reactor vessel to form a coating on the particles while continuously or intermittently agitating the reactor system.

### CROSS-REFERENCE TO RELATED APPLICATIONS

This U.S. application is a continuation application of International Application No. PCT/US23/63738, filed Mar. 3, 2023, which claims benefit of U.S. Provisional Application No. 63/336,863, filed Apr. 29, 2022, U.S. Provisional Application No. 63/330,166, filed Apr. 12, 2022, and U.S. Provisional Application No. 63/316,947, filed Mar. 4, 2022. These provisional applications are incorporated herein by reference in their entireties for all purposes.

### FIELD

Embodiments of the present disclosure provide novel devices and methods for maintaining particle or microparticle distribution and/or reducing or preventing particle or microparticle agglomeration and/or adherence to surfaces in a chemical vapor deposition system and, for example, in chemical layer deposition, and, further, for example, in atomic layer deposition (ALD). In certain embodiments, the device includes one or more agitating (e.g., vibrating, impacting, sonicating (also referred to as ultrasonicating)) devices in communication with a reactor vessel of a reactor system.

### BACKGROUND

Particle Atomic Layer Deposition (ALD) is a gas or vapor-phase process where thin conformal shells of chemical compounds are grown atomic layer by atomic layer on the surfaces of particles including but not limited to nanoparticles and microparticles of targeted agents or microparticles of stabilized formulations using repeated multi-step reaction sequences to create coated microparticles. Generally, chemical precursors or agents (e.g., biological, chemical, microbial, or pharmaceutical agents) are generated into thermostable powder particles so that all surface sites can be evenly exposed throughout the process and uniform coatings are obtained. As these coated microparticles or particles are formed, floating particles can stick to reactor walls or to filters. As the coating process proceeds, wall deposits increase in thickness as more particles stick to the walls and these deposits solidify further onto the reactor walls and filters, which frequently necessitates stopping of the coating process and manually stirring the deposits or simply removing the deposits from the walls and filters (e.g., scraping). The points of contact between particles of the targeted agents or stabilized formulations including the deposits and particles adhered to the reactor walls or filters are not exposed to the chemical precursors to form uniformly coated particles or microparticles. Thus, when the wall deposits are redispersed, contact points can provide weak and uneven sections of coating and, in certain cases, the contact points can form holes in the coating allowing the target agents or stabilized formulations to leak out. Therefore, there is a need for improved systems for reducing or preventing agglomeration or particle adherence during these processes.

### SUMMARY

Embodiments of the present disclosure provide novel devices and methods for maintaining particle or microparticle distribution and/or reducing or preventing particle or microparticle agglomeration and/or adherence to surfaces in chemical layering or coating (e.g., atomic layer deposition (ALD)). In certain embodiments, a particle or microparticle is about 0.01 to about 1,000 microns. In some embodiments, a particle or microparticle is about 0.01 to about 1,000 microns before or after coating is completed by a reactor system disclosed herein. In some embodiments, devices disclosed herein include one or more agitating (e.g., vibrating, impacting, or sonicating) devices in communication with or directly associated with a reactor vessel of reactor system (e.g., ALD).

In certain embodiments and further to paragraph above, a system for coating microparticles or particles is disclosed having improved features. In accordance with these embodiments, a reactor system for coating microparticles includes a reactor vessel having a processing chamber for housing a plurality of microparticles being coated or to be coated. In certain embodiments, the reactor vessel can further include an inlet at a first end of the reactor vessel; an outlet at a second end of the reactor vessel; and one or more side walls within the reactor vessel. In other embodiments, the reactor vessel is configured to allow flow of a process gas through the processing chamber while retaining the plurality of microparticles within the processing chamber between the first end of the reactor vessel and the second end of the reactor vessel, the interior surfaces defining an internal volume, wherein the reactor vessel is configured to receive the plurality of particles or microparticles; and one or more agitator(s) associated with or coupled to, the reactor vessel for preventing or reducing agglomeration of the plurality of microparticles and coated microparticles within the reactor vessel. In some embodiments, the one or more agitator(s) can include at least one of an agitator (e.g., a sonicator, an impactor and/or a vibration device) alone or in combination with an impactor or other vibration device. In certain embodiments, the agitator can be a sonicator configured to deliver mechanical energy in the form of waves such as sound waves or vibrations through a wave propagating structure such as a collar affixed or associated to the reactor vessel. In some embodiments, the agitator is configured or programmed to prevent or reduce adherence of microparticles or coated microparticles to a surface of the reactor vessel (e.g., walls or nodules or protrusions within the reactor vessel). In certain embodiments, the agitator is configured to transfer mechanical oscillations, pulses, or vibrations to the reactor vessel. In other embodiments, two or more agitators can be configured to transfer combinations of mechanical oscillations, pulses, or vibrations to the reactor vessel. In accordance with these embodiments, the oscillations, pulses, or vibrations to the reactor vessel reduce or eliminate the plurality of particles or microparticles from at least one of agglomerating to one another, agglomerating or attaching to a filter within the reactor vessel, agglomerating or attaching to another component within the reactor vessel and/or adhering to an interior side wall, nodule, protrusion, or other surface of the reactor vessel. In certain embodiments, the agitator can be a pneumatic hammer, a solenoid hammer, or similar device, which can be used to agitate or vibrate a table or stand supporting a reactor system and/or can be directly mounted to the reactor vessel to agitate or vibrate the reactor vessel.

In certain embodiments and further to paragraphs [0004]-[0005] above, the one or more agitator(s) is (are) directly or indirectly connected to the reactor vessel or an inlet or outlet of the reactor vessel. In accordance with these embodiments, a collar or sleeve can surround the reactor vessel and further directly or indirectly connect to the one or more agitator(s), for example, sonicating, impacting, or vibrating device(s) associated with the reactor vessel. In other embodiments, a connector can be used to directly, or indirectly, link the one or more agitator(s) with the collar which is associated with or coupled to the reactor vessel. In other embodiments, the collar or sleeve can further include a vibration absorbing or sonication absorbing or impacting absorbing material for reducing damage to the reactor vessel while allowing adequate agitation (e.g., sonication, impact, or vibration) to the reactor vessel to reduce or eliminate agglomeration or adherence of the plurality of particles or microparticles or coated microparticles to the reactor vessel.

In certain embodiments and further to paragraphs [0004]-[0006] above, the one or more agitator can be in electrical communication or remote communication with a controller configured to control the agitation parameters, including but not limited to, power output, frequency, intensity, timing of the mechanical energy delivery (e.g., periodic, cyclical, intermittent, continuous, only during certain parts of the process). In other embodiments, the agitator is directly or indirectly connected to the reactor vessel or an inlet or outlet of the reactor vessel for delivering agitation to the reactor vessel or an inlet or outlet of the reactor vessel. In accordance with these embodiments, the agitator (e.g., sonicator, impactor, or vibrator) sonicates, impacts, or vibrates the reactor vessel at the time of or after one or more coatings of the plurality of microparticles randomly, pre-programmed or by periodic cycles. In certain embodiments, sonication, impacting, or vibration to the reactor vessel by the agitator includes a duration of less than a second up to a few minutes per ALD cycle or every other ALD cycle or other regimen. In other embodiments, sonication, impacting, or vibration to the reactor vessel by the agitator includes varying durations or increasing durations depending on the number of coatings and/or the number of microparticles being coated. In some embodiments, the agitator can be operated intermittently or continuously.

In certain embodiments and further to paragraphs [0004]-[0007] above, the reactor system can include one or more impactor(s). In other embodiments, the reactor system can include an impactor associated with or coupled to the reactor vessel and configured to impact the reactor vessel to reduce the microparticles from at least one of agglomerating to one another and adhering to at least one of the reactor vessel chamber walls, the inlet filter, and the outlet filter. In some embodiments, the impactor can be a pneumatic or an electrically actuated hammer configured to impact the reactor vessel continuously or intermittently. In certain embodiments, the impactor can be coupled to a supporting structure (e.g., table) in which the reactor vessel is supported thereto.

In other embodiments and further to paragraphs [0004]-[0008] above, the reactor system for coating particles or microparticles can include one or more vibration device to induce low-frequency oscillations (<300 Hz) for aiding the powder fluidization of the coated particles or microparticles and to assist in the reduction of, or prevention of wall deposits and agglomeration in the powder bed. In some embodiments, the one or more vibration device can include one or more vibration motors mounted to a table or a vibration table. In accordance with these embodiments, the reactor system can then be attached to the table or vibration table so that the vibrations of the one or more vibration device are directly transferred to a powder bed (e.g., reaction chamber) harboring the particles or microparticles being coated by the reactor system.

In other embodiments and further to paragraphs [0004]-[0009] above, the reactor system for coating particles or microparticles can include combinations of sonication, impact, and/or vibration devices to minimize wall deposits and agglomeration in the powder bed harboring the particles or microparticles being coated by the reactor system disclosed herein.

In other embodiments and further to paragraphs [0004]-[0010] above, novel systems are provided for creating coated particles or microparticles from targeted antigens or agents, thermostable agents, thermal stable immunogens, thermal stable chemicals such as pharmaceutical agent, and thermal stable immunogenic formulations. In certain embodiments, reactor systems for creating coated particles or microparticles from thermostable agents include one or more of sonicating, impactor, or vibrating device, attached, or associated with a reactor for creating more uniformly coated microparticles with reduced or eliminated agglomeration or microparticle adherence. In some embodiments, reactor systems for creating coated microparticles include one or more of a sonicating, impactor, or vibrating device, attached, or associated with a reactor for creating more uniformly coated glassy particles containing at least one antigen. In other embodiments, reactor systems for creating coated microparticles from thermostable agents include one or more of a sonicating, impacting, or vibrating device, attached, or associated with a reactor for creating more uniformly coated microparticles with reduced or eliminated agglomeration or microparticle adherence.

In certain embodiments and further to paragraphs [0004]-[0011] above, thermostable chemicals, agents, or antigens contemplated of use for coating in reactor systems disclosed herein can include but are not limited to any pharmaceutical agent capable of being coated by ALD or other coating process. In some embodiments, antigens, or other agents of particles or microparticles contemplated herein can initially be embedded in an organic glassy matrix or a glass-forming agent or other stabilizing agent prior to introduction to a reactor system disclosed herein for coating (e.g., ALD). In certain embodiments, antigens, or other agents of particles or microparticles contemplated herein are thermostabilized in order to maintain integrity and reduce degradation at temperatures up to about 60° C. In some embodiments, at least a primary and a boost dose of the same antigens can be created in particles or microparticles disclosed herein and coated by ALD devices disclosed herein with reduced agglomeration and adherence. In other embodiments, two or more different antigens or agents can be dispersed in a single microparticle in the same or different layers. In other embodiments, immunogenic agent-containing particles can include immunogenic agents against two or more pathogens either in the same or in separate particles.

In other embodiments and further to paragraphs [0004]-[0012] above, antigen-, agent- or immunogenic agent-containing particles or microparticles disclosed herein can have a central or innermost antigen-, agent- or immunogenic agent-containing microparticle or particle including at least one immunogenic agent, agent or antigen and optionally, at least one glass-forming agent; and one or more outer coating layers using reactor systems disclosed herein for covering or encasing the central agent-containing microparticle or particle with reduced adherence of the microparticles or particles. In some embodiments, a primary antigen-containing or immunogenic agent-containing or agent-containing microparticle composition can be dehydrated by lyophilization, vacuum-drying, spray drying, or spray-freeze-drying prior to introducing to a reactor system disclosed herein. In accordance with these embodiments, one, two, three, four, five or more coating layers can encase the thermostable microparticles or particles where the coating layers are readily dissolvable in a subject once administered, to expose the immunogenic agent-containing particles or antigen or agent to the subject. In certain embodiments, systems and features disclosed herein provide for production of more uniformly coated particles with reduced loss and reduced side effects of adherence and agglomeration leading to an increase in production, a more reliable end-product and reduce costs in production.

In other embodiments and further to paragraphs [0004]-[0013] above, methods are provided for using a reactor system such as an ALD system or other coating system with a sonicator, impactor, or vibrator disclosed herein for generating coated particles or microparticles having reduced or eliminated adherence to the reactor vessel and/or filter. In accordance with these embodiments, the sonicator, impactor, or vibrator disclosed herein for generating coated microparticles having reduced or eliminated adherence to the reactor vessel provides improved uniformity of coated particles, reducing issues of imperfections of the coated particles such as holes or incomplete coating of one or more coating layers on the microparticle for increased productivity with improved and more reliable production of product. In other embodiments, the sonicator, impactor, or vibrator associated directly or indirectly with a reactor vessel disclosed herein can reduce adherence and/or agglomeration by at least 1.0% up to 100% compared to systems without an agitator (e.g., a sonicator associated directly or indirectly with a reactor vessel.

In other embodiments and further to paragraphs [0004]-[0014] above, the at least one immunogenic agent or antigen or other agent can include, but is not limited to, one or more of a polypeptide or fragment thereof, a polynucleotide, a pharmaceutical agent or chemical, a whole organism or derivative or polypeptide derived therefrom or a combination thereof. In accordance with these embodiments, the at least one immunogenic agent or antigen or other agent can include, but is not limited to, one or more of: a viral antigen, a bacterial antigen, a toxin, a fungal agent or other pathogenic agent, a pharmaceutical agent (e.g., anti-cancer, anti-inflammatory or other agent) or a combination thereof. In some embodiments, the at least one immunogenic agent can also include, but is not limited to, a recombinant peptide, a recombinant protein, a peptide derived from a target protein or pathogen, a synthetic peptide or protein, a virus-like particle, a live virus, a live, attenuated virus, an inactivated virus, a bacterial antigen, a bacteriophage or phage or a combination thereof.

In some embodiments and further to paragraphs [0004]-[0015] above, each layer of the one or more outer coating layers can include at least one oxide agent. In certain embodiments, the one or more coating layers can include at least one of a metallo-organic material, metal oxides, metal alkoxides, and/or aluminum-based coating layer. In accordance with these embodiments, one or more outer coating layers can include, but is not limited to, one or more of aluminum oxide, an aluminum alkoxide (e.g., alucone), silicon dioxide (SiO₂), titanium dioxide (TiO₂), or silicon nitride (Si₃N₄) or zinc oxide (ZnO), alone or in a suitable combination composition. In some embodiments, one or more outer coating layers can include, but is not limited to, one or more of aluminum oxide, an aluminum alkoxide (e.g., alucone), silicon dioxide (SiO₂), titanium dioxide (TiO₂), or zinc oxide (ZnO), alone or in a suitable combination composition for coating a thermostable agent contemplated herein. In certain embodiments, the one or more coating layers of use in systems disclosed herein does not include silicon nitride (Si₃N₄).

Yet other embodiments provide for kits that can include at least one sonicator, impactor, or vibrator disclosed herein and components for attaching or associating the agitator, vibrator or sonicator to a reactor vessel of a reactor system or coating system. In other embodiments, a kit can include tools for attaching the agitator, vibrator or sonicator to a reactor vessel and optionally, include a collar and/or cuff and/or connector (e.g., screw or connector).

### BRIEF DESCRIPTION OF THE FIGURES

The accompanying drawings are incorporated into and form a non-limiting part of the specification to illustrate several examples of the present disclosure.

FIG. 1 represents a schematic view of an ALD manifold illustrating a transducer attached to the reactor in accordance with certain embodiments disclosed herein.

FIGS. 2A and 2B represent in 2A, a cross-sectional view illustrating a transducer attached to a reactor with a collar; and in 2B an exemplary reactor system having 2 sonication devices associated with a reaction chamber in accordance with certain embodiments disclosed herein.

FIG. 3 is a photograph of an agitator (e.g., a sonicator) attached to a reactor vessel with a collar in accordance with certain embodiments disclosed herein.

FIGS. 4A and 4B illustrate in 4A, a top view illustrating an agitator (e.g., a sonicator) and collar assembly; and in 4B, is a schematic of an impactor associated to a reactor system in accordance with certain embodiments disclosed herein.

FIG. 5 is a cross-sectional view illustrating a reactor vessel of a reactor system and microparticle and/or coated microparticles behavior in a fluidized bed without features disclosed herein and in accordance with certain embodiments disclosed herein.

FIG. 6 is a schematic diagram illustrating the formation of coating layers in a reactor system accordance with certain embodiments disclosed herein.

FIGS. 7A-7B are schematics illustrating particle agglomeration (FIGS. 7A-7B) and/or particle adhesion (FIG. 7B) and how these effects can cause defective coatings and potentially holes in coated particles due in part to reaction chamber adhesion and agglomeration to other particles in accordance with certain embodiments disclosed herein.

FIG. 8 is a schematic diagram that illustrates TMA-H2O chemistry as one example of a coating process.

FIG. 9 is a flowchart of an overview of an exemplary ALD method in accordance with certain embodiments disclosed herein.

FIG. 10 is a flowchart of exemplary coating steps of an ALD method in accordance with certain embodiments disclosed herein.

FIG. 11 is an exemplary table illustrating some properties or features of coating processes disclosed herein under various conditions of a reactor system in the presence (+) or absence (−) of a particular feature or component in accordance with certain embodiments disclosed herein.

FIG. 12 is an exemplary chart illustrating particle size distribution of spray dried samples before and after coating by ALD without sonication after each precursor dose in accordance with certain embodiments disclosed herein.

FIGS. 13A-13C are exemplary photographic images illustrating buildup observed on an outlet filter after approximately 100 coating cycles, reactor content after approximately 100 coating cycles, and reactor content after 250 coating cycles in absence of ultrasonic agitation, respectively in accordance with certain embodiments disclosed herein.

FIG. 14 is a representative chart illustrating particle size distribution of spray dried powder before and after coating with approximately 250 coating cycles that included agitation or adherence disruption (e.g., sonication) after each precursor dose in accordance with certain embodiments disclosed herein.

FIGS. 15A-15B are photographic images illustrating reactor content after 250 uninterrupted coating cycles with intermittent agglomeration and/or adherence disruption, and buildup on an outlet filter after 250 uninterrupted coating cycles with intermittent agglomeration and/or adherence disruption, respectively in accordance with certain embodiments disclosed herein.

FIG. 16 is an exemplary graph illustrating release or leaking of a target molecule or pharmaceutical agent after coating over a period of time in accordance with certain embodiments regarding agitation as disclosed herein.

### DETAILED DESCRIPTION

In the following sections, various exemplary compositions and methods are described in order to detail various embodiments. It will be obvious to one skilled in the art that practicing the various embodiments does not require the employment of all or even some of the specific details outlined herein, but rather that concentrations, times and other specific details can be modified through routine experimentation. In some embodiments, well known methods or components have not been included in the description.

Particle Atomic Layer Deposition (ALD) is a vapor-phase process where thin conformal shells or layers of chemical compounds are grown atomic layer by atomic layer on the surfaces of powders using repeated multi-step reaction sequences. In certain embodiments disclosed herein, fluidized beds, unlike other systems used in the relevant art, can be used to continuously agitate the powder particles using a gas stream as chemical precursors are added to the fluidized bed so that all surface sites are evenly exposed throughout the process and uniform coatings are obtained.

Fluidization occurs when the drag force of the fluidizing gas exceeds the downward force of gravity on the particles due to their mass and the bed expands in volume as the particles separate from each other as they are surrounded by the gas stream. This gas velocity where this separation first occurs is called the minimum fluidization velocity and depends on the size, shape, and density of the particles. As the flow rate of the fluidization gas increases further, gas bubbles form and ultimately, particles are entrained from the bed. The fluidization behavior depends on the size and cohesiveness of the particles and cohesive powders with sizes less than 30 micron are difficult to fluidize as individual particles and rather fluidize as agglomerates and/or form channels through for the gas that bypasses most of the bed. Powders relevant for pharmaceutical applications demonstrate such behavior and adequate fluidization and efficient chemical coating is challenging.

One issue using these ALD systems is that with certain particle sizes and particle densities, cohesion between particles increases due to either electrostatic interaction, van-der-Waals forces, capillary forces, or hydrogen bonds or other features or any combination of these conditions. Hydrogen bonds or capillary forces can be dominant, for example, during a water dosing cycle of alumina ALD at low deposition temperatures (e.g., less than 100° C.). Therefore, with strong cohesive forces, clusters of agglomerated particles can form in the bulk phase of the powders and these clusters are difficult to disperse, even by the forces that the fluidizing gas of the fluidized bed can exert on the particles. As a result, fluidization poses many challenges, and instead of uniform mixing of the powder bed, as observed in ideal fluidization, channels can form in the fluidized bed, or the powder can lift and form a plug at an end of the chamber. The lack of even or uniform mixing during coating processes such as ALD can then result in loss of product and in certain cases, an inferior product produced due to uneven coating of agglomerated particles and particles that adhere to the walls or other surfaces of the reactor chamber.

In addition, the gas stream used to fluidize and agitate powders or particles and/or carry gas-phase reaction components to the powders or particles can carry some of the particles into the headspace of a system where they can touch the reactor walls or even reach the particle filter at the reactor outlet used for containing the powder in the reactor (elutriation). These floating particles then tend to stick to reactor walls, or to the filters if they have adhesive properties as described above resulting in additional loss of product or uneven coating, for example.

As the coating process proceeds, the agglomerates or wall deposits solidify further as the coating near the contact points of the particles in the agglomerates increases in thickness to eventually form a stable neck. In certain cases, points of contact between the particles cannot be exposed to the chemical precursors to the same extent as accessible surfaces and coatings are thinner at these areas and in some cases form holes. When such agglomerates are redispersed by milling or scraping the reactor walls, contact points can provide weak sections of coating that is less protective than the sections of the coatings that were continuously exposed during the ALD process having a more uniform surface. Some areas can even be absent of coatings, depending on the proximity of the contact points, or the fracturing process can lift layers off some surfaces. The thickness of the agglomerated particle deposit on the reactor walls can also increase with increasing cycle numbers and process duration as more particles are elutriated from the bulk powder and contact the reactor walls causing for example, loss of product and less uniformity with the resulting composition of coated particles or microparticles.

In addition, fractions of the wall or filter buildup can randomly break off in agglomerated chunks during the coating process and join the bulk of the fluidized bed. The chunks are often sturdy enough to maintain most or at least some of their integrity throughout the remainder of the coating process and thus the particles that are part of these loose agglomerates can often fail to be evenly coated.

In certain embodiments disclosed herein, devices and methods of use thereof are disclosed that improve coating outcome of reactor system coated particles or coated microparticles. In accordance with these embodiments, having uniform coatings of hard-to-fluidize and cohesive powders requires sufficient mechanical energy input to continuously, or intermittently, disperse agglomerates and dislodge wall or filter particle deposits. With decreasing particle sizes and particle density, cohesion between particles and reactor walls, particles increase due to one or more of electrostatic interaction, van-der-Waals forces, capillary forces, or hydrogen bonds. Hydrogen bonds and capillary forces can be dominant during the water dosing cycle of alumina ALD at low deposition temperatures (e.g., less than 100 C), often needed for coating of pharmaceutical particles. Such particles include microparticles, including, but not limited to, spray-dried glassy agent or carbohydrate or other formulations in a size range of about a few micrometers often used in pharmaceutical applications. As a result of those strong cohesive forces, in addition to forming difficult to disperse agglomerates or clusters in the bulk phase, particles can form stable deposits on the reactor wall that increase in thickness with increasing processing time and deposition layering. Strong adhesion forces of small particles attached to surfaces such as reactor walls can require those surfaces to be accelerated in excess of 1000 m²/s or 100 g (1 g ˜10 m²/s)) to overcome these adhesion forces and dislodge the particles from the surfaces. It has been demonstrated that accelerations in excess of 10000 g were used to dislodge more than half of glass spheres from a glass surface and more than 50000 g to dislodge 5 micrometer aluminum particles from an aluminum surface in a dry environment. Adhesion forces such as hydrogen bonds or capillary forces may be even stronger for the glassy, pharmaceutical agent containing organic particles described herein, especially in the presence of moisture or other ALD chemical as required for the coating process. Conventional devices and methods that are used to aid fluidization such as low-frequency mechanical vibrations fail to provide sufficient acceleration to reduce or prevent agglomeration and/or adherence and to dislodge reactor wall and filter deposits. The purge gas used for fluidization purposes does not exert sufficient force to prevent, reduce or remove agglomerated or attached particles from the walls, especially at the low pressures and low feed rates often used for reactor system (e.g., ALD) coating processes. Layers coating the reactor walls can be physically scraped off and redispersed intermittently to minimize uneven coatings; however, this scraping process is disruptive to the coating process, is timely, requires stopping the process, and can cause product loss. In addition, maintaining sterility will be difficult in part due to particles exposed to potential contaminants as can happen during a scraping process while the system is open. Additionally, the size and quality of the coating of the dislodged particles is frequently uneven or not uniform and may need to be discarded without use of the system disclosed herein.

Bulk phase collected after completion of the coating process in these examples typically contains a fraction of larger agglomerates and primary particles due to some of the powder remaining mobilized throughout the process. The fraction of ‘loose’ powder can approach zero for smaller sample sizes as all the particles become immobilized or adhered to reactor walls and only agglomerates that dislodged at some point from the walls in the process and can be too large to be carried (elutriated) by the fluidization gas and remain as bulk material.

Other issues that can occur during these processes, include where the purge gas stream to agitate the powders carries some of the particles into the headspace where they can touch the reactor walls or even reach the particle filter at the reactor outlet and/or inlet used for containing the microparticle-containing powder in the reactor during exposure to gas-phase reaction components (elutriation). These floating particles can then stick to reactor walls, or to the particle filters reducing coating uniformity of the adhered particles or microparticles.

In other embodiments and further to paragraphs to above, a mechanical energy device disclosed herein to reduce agglomeration and/or adhesion in a reactor vessel is can be a mechanical energy device that can deliver enough acceleration to overcome wall adhesion forces and agglomeration (e.g., >10\hat{ }7 m/s2, or >10\hat{ }6, m/s2) where any system capable of delivery this acceleration without damaging particles in a projected time-period is contemplated herein. In other embodiments, one or more agitator(s), for example, vibrator(s), impactor(s), and/or or sonicator(s), disclosed herein can be tunable. In certain embodiments, one or more agitator(s) disclosed herein can be tunable in order to deliver optimum force for dislodgement at an optimum time interval. In accordance with these embodiments, the one or more agitator(s) controller that is tunable can mean that the one or more agitator(s) causes less than 5.0% damage or that has an operational interval less than what could or would cause less than about 5.0% friability of the particles or microparticles, or less than about 1.0%, or less than about 0.1% friability of the particles or microparticles being coated in the reactor system. In accordance with these embodiments, the one or more agitator(s) controller that is tunable can mean that the one or more agitator(s) causes less than 5.0% damage or that an operational interval is less than that would causes less than about 5% friability of the particles or microparticles, or less than about 1.0%, or less than about 0.1% friability of the particles or microparticles being coated in the reactor system.

In certain embodiments and further to paragraphs to above, systems disclosed herein include Particle Atomic Layer Deposition (ALD) as a vapor-phase process where thin conformal shells of chemical compounds are grown atomic layer by atomic layer on the surfaces of powders using repeated multi-step reaction sequences. In accordance with certain embodiments, fluidized beds can be used to continuously agitate the powder particles in a gas stream at reduced or elevated pressure as the chemical precursors are added so that all surface sites are evenly exposed throughout the process and uniform coatings are obtained for improved outcome alone or in combination with other devices disclosed herein.

In certain embodiments and further to paragraph to above, the devices and methods described herein provide means of implementing mechanical forces, including cyclic acceleration (vibration) with sufficient intensity to overcome adhesion particle/particle and particle/wall adhesion forces for micron and sub-micron sized particles that lead to wall deposits and agglomeration. Such forces can be obtained with ultrasonic agitation where small amplitude vibrations at high frequencies result in wall accelerations and decelerations in the range of 1000 s and 10000 s of g's (1 g ˜10 m²/s, gravity). These vibrations disrupt the particle/wall and particle/particle interactions on a microscopic scale but may not provide sufficient amplitude to effectively remove the dislodged particles sufficient distances from the reactor surfaces to prevent dynamic reattachments. In some embodiments, superimposed low frequency vibrations with larger amplitudes improve coated particle outcome such as those that can be obtained with vibration motors or mechanical impactors/hammers aid the dislodging of particles attached to reactor surface, likely by providing additional separation for the dislodged particles from the reactor walls to minimize reattachment and result in re-immersion of the dislodged particles into the bulk powder phase for optimized coating quality and product yield.

Other embodiments and further to paragraphs [0036]-[0047] above, provide for novel devices and methods for maintaining microparticle distribution and/or reducing or preventing microparticle agglomeration and/or adherence to surfaces in reactor vessel of the system such as atomic layer deposition (ALD) system and/or improving delivery or syringability of coated microparticle compositions or formulations contemplated herein. In certain embodiments, reactor systems disclosed herein further include a device for additional agitation. In accordance with these embodiments, the device can include an agitator (e.g., a sonicator, which can be, for example, an ultrasonic transducer) in contact with a reactor vessel of a reactor system (e.g., ALD). In other embodiments, the device can further include at least a second device for disrupting agglomeration or adherence of coated particle or microparticles in a reactor vessel disclosed herein. In certain embodiments, the at least second device can be an impactor, such as a pneumatic hammer or solenoid hammer (or similar controllable striking device). In certain embodiments, the second device can be a vibrating device, such as a vibrating motor. In other embodiments, a reactor system disclosed herein can include a combination of agitators, for example, including but not limited to, sonicator, impactor, and/or vibration motor. In some embodiments, a reactor system can include a combination of one or more sonicators, one or more impactors, and/or one or more vibration motors.

In certain embodiments and further to paragraphs [0036]-[0048] above, a system for coating microparticles or particles is disclosed having improved features. In accordance with these embodiments, a reactor system for coating microparticles includes a reactor vessel including a processing chamber having a plurality of microparticles being coated or to be coated. A processing chamber can define a cylindrical tube, cone, cube or other configuration and a shaft collar can be secured to the cylindrical tube, cone, cube, or other configuration of the processing chamber. The reactor vessel further includes an inlet at a first end of the reactor vessel; an outlet at a second end of the reactor vessel; and one or more walls, noduled, or surfaces within the reactor vessel. In accordance with these embodiment, the reactor vessel is configured to allow flow of process gases or purge gas (e.g., argon, TMA vapor, water vapor, and mixtures thereof) through the processing chamber while retaining the plurality of microparticles within the processing chamber between the first end of the reactor vessel and the second end of the reactor vessel, the interior surfaces defining an internal volume, where the reactor vessel is configured to receive the plurality of particles or microparticles; and an agitator, for example, sonicating, impacting, and/or vibrating device associated with the reactor vessel for preventing or reducing agglomeration or adherence of the plurality of particles and/or microparticles and coated microparticles within the reactor vessel (e.g., on surfaces within the reactor vessel).

In some embodiments and further to paragraphs [0036]-[0049] above, the agitator is a sonicator (e.g., an ultrasonic transducer) that is configured or programmed to prevent or reduce adherence of particles or microparticles or coated microparticles to any surface of the reactor vessel (e.g., walls or nodules or protrusions within the reactor vessel or filters). In certain embodiments, the agitator is a sonicator (e.g., an ultrasonic transducer) that is configured to transfer mechanical energy in the form of sound waves, pulses, or vibrations to the reactor vessel to reduce agglomeration or adherence of the particles or microparticles within the reactor vessel. In accordance with these embodiments, the waves, pulses, or vibrations to the reactor vessel reduce or eliminate the plurality of microparticles from at least one of agglomerating to one another, agglomerating or attaching to a filter within the reactor vessel, agglomerating or attaching to another component within the reactor vessel and/or adhering to an interior side wall, nodule, protrusion, filter, or other surface of the reactor vessel.

In certain embodiments and further to paragraphs [0036]-[0050] above, the agitator is a sonicator (e.g., an ultrasonic transducer) that is coupled to the reactor vessel directly or indirectly. Additionally, or alternatively, the sonicator can be coupled to an inlet or outlet of the reactor vessel. In accordance with these embodiments, a sound wave or acoustic wave propagating structure such as a collar or sleeve component can surround or be attached to the reactor vessel and further directly or indirectly connect to the sonicator. In other embodiments, a connector (e.g., a sonicator connector) can be used to directly, or indirectly, link the sonicator with the reactor vessel.

In other embodiments and further to paragraphs [0036]-[0051] above, the collar or sleeve and/or connector can further include a vibration absorbing material for reducing damage to the reactor vessel while allowing adequate vibration, impacting, or sonication to the reactor vessel to reduce or eliminate agglomeration of the plurality of microparticles or particles or coated microparticles or particles. In certain embodiments, a vibration reducing material can include, but is not limited to, foam, rubber, composite material, or other suitable material.

In certain embodiments and further to paragraphs [0036]-[0052] above, the agitator delivers mechanical energy to the reactor vessel during or after one or more coatings of the plurality of microparticles or particles. In accordance with this embodiment, the agitator is a sonicator (e.g., an ultrasonic transducer) that can deliver mechanical energy in the form of sound waves to the reactor vessel during or after one or more coatings of the plurality of microparticles or particles. In some embodiments, a controller of the sonicator can be programmed to cause the delivery of the mechanical energy randomly, pre-programmed, by periodic cycles or by a variety of pre-programmed cycles. In certain embodiments, sonication by the sonicator can occur less than a second up to a few minutes. In other embodiments, sonication varies in duration or occurs in increasing durations depending on the stage of the coating process such as the number of coatings and/or the number of microparticles or particles being coated. In some embodiments, sonication is controlled by a pre-set program or by computer programmed to cause the agitator to sonicate or other timing device. In certain embodiments, the agitator can be operated intermittently to avoid reaching a pre-determined threshold temperature (e.g., overheating the reactor vessel and/or the device due to thermal energy released by the sonicator (e.g., ultrasonic transducer) at least due to device inefficiencies). In some embodiments, ultrasonic agitation (e.g., sonication) disclosed herein could cause damage or breakage of the particles or microparticles, and therefore is limited in duration and controlled to provide effective deagglomeration and removal from the walls while minimizing the damage to the particles or microparticles.

In other embodiments, and in further considerations of the paragraphs above, novel systems are provided for creating coated microparticles from targeted antigens, thermostable agents, thermal stable chemicals such as pharmaceutical agent, and thermal stable immunogenic formulations. In certain embodiments, reactor systems for creating coated microparticles or particles from thermostable agents include an agitator, for example, a sonicating (e.g., ultrasonic transducer), impacting, or vibrating device, attached, or associated with a reactor for creating more uniformly coated microparticles with reduced or eliminated agglomeration or microparticle adherence. In some embodiments, systems for creating coated microparticles include an agitator, such as a sonicating (e.g., ultrasonic transducer), impacting, or vibrating device, attached, or associated with a reactor for creating more uniformly coated glassy particles containing at least one antigen. In other embodiments, reactor systems for creating coated particles or microparticles from thermostable agents include an agitator, such as a sonicating (e.g., ultrasonic transducer), impacting, or vibrating device, attached, or associated with a reactor for creating more uniformly coated microparticles with reduced or eliminated agglomeration or microparticle adherence further include a pneumatic hammer, solenoid hammer, or similar device for vibrating a table or stand holding a reactor system.

In certain embodiments and further to paragraphs [0036]-[0054] above, microparticles or particles or thermostable microparticles or particles thereof or powders containing microparticles or particles introduced to a reactor vessel contemplated herein are not removed from the reactor vessel and re-introduced to the reactor vessel for additional coatings. In other embodiments, microparticles or particles or thermostable microparticles or particles thereof or powders containing microparticles or particles introduced to a reactor vessel contemplated herein are not removed from the reactor vessel, impacted, or stirred or sonicated and then re-introduced to the reactor vessel for additional coatings. In all embodiments disclosed herein, the reactor vessel is devoid of a sieve for use intermittently during the coating process.

In other embodiments and further to paragraphs [0036]-[0055] above, a removable sieve can be used to sieve particles before introduction to the reactor or prior to coating or used prior to the coating processes to remove agglomerates that may be present in the starting material or used after completion of a coating process. In accordance with these embodiments, sieving can be assisted by ultrasonic (or sonic) vibration, using transducers described herein. In certain embodiments, particles can be sieved prior to loading in the processing chamber of a reactor system disclosed herein. In other embodiments, a removable sieve can be used at the end of the coating process when all coats are completed, as needed. In addition, a final quality control sieving process to can also be facilitated by brief exposure to suitable drying agents to minimize the cohesive properties of coated particle or microparticle products. In other embodiments, the reactor vessel is devoid of a stirring mechanism. In certain embodiments, the ultrasonic agitator or sonication system can be utilized to reduce or prevent agglomeration or adherence of particles to the chamber walls and filters. In accordance with these embodiments, sonication is not used to provide fluidization of the microparticles.

In certain embodiments and further to paragraphs [0036]-[0056] above, thermal stable chemicals or agents or antigens contemplated of use for coating in reactor systems disclosed herein can include, but are not limited to, any pharmaceutical agent or biologic or chemical agent capable of being coated by ALD or other coating process. In some embodiments, antigens can initially be embedded in an organic glassy matrix or a glass-forming agent or thermostable or thermostabilized prior to introduction to a reactor system disclosed herein for coating (e.g., ALD). In other embodiments, at least a primary and a boost dose of the same antigens can be encased in coated microparticles disclosed herein having reduced agglomeration or adhesion using devices disclosed herein. In other embodiments, two or more different antigens or agents or compounds can be dispersed in a single microparticle in the same or different layers or multiple microparticles each containing one or more antigen or pharmaceutical agent can be mixed in a single composition. In other embodiments, agent-containing particles can include immunogenic agents against two or more pathogens either in the same or in separate particles.

In other embodiments and further to paragraphs [0036]-[0057] above, antigen-, agent- or immunogenic agent-containing particles or microparticles disclosed herein can have a central or innermost antigen-, agent- or immunogenic agent-containing microparticle or particle including at least one immunogenic agent, agent or antigen and optionally, at least one glass-forming agent; and one or more outer coating layers using reactor systems disclosed herein for covering or encasing the central agent-containing microparticle or particle with reduced adherence of the microparticles or particles. In some embodiments, a primary antigen-containing or immunogenic agent-containing or agent-containing microparticle composition can be dehydrated by lyophilization, vacuum-drying, spray drying, or spray-freeze-drying prior to introducing to a reactor system disclosed herein. In accordance with these embodiments, one, two, three, four, five or more coating layers can encase the thermostable microparticles or particles where the coating layers are readily dissolvable in a subject once administered, to expose the immunogenic agent-containing particles or antigen or agent to the subject. In certain embodiments, systems and features disclosed herein provide for production of more uniformly coated particles with reduced loss and reduced side effects of adherence and agglomeration leading to an increase in production, a more reliable end-product and reduce costs in production.

In other embodiments and further to paragraphs [0036]-[0058] above, methods are provided for using the reactor system (e.g., ALD system) with one or more agitator disclosed herein for generating coated microparticles having reduced or eliminated adherence to the reactor vessel and/or filter. In accordance with these embodiments, the one or more agitator disclosed herein for generating coated microparticles having reduced or eliminated adherence to the reactor vessel provides improved uniformity of coated particles, reducing issues of imperfections of the coated particles such as holes or incomplete coating of one or more coating layers on the microparticle for increased productivity with improved and more reliable production of product. In other embodiments, the one or more agitator coupled directly or indirectly with a reactor vessel disclosed herein can reduce adherence and/or agglomeration by at least 1.0% up to 100% compared to systems without one or more agitator(s) coupled directly or indirectly with a reactor vessel.

In other embodiments and further to paragraphs [0036]-[0059] above, at least one immunogenic agent or antigen or other agent can include, but is not limited to, one or more of a polypeptide or fragment thereof, a polynucleotide, a pharmaceutical agent or chemical, a whole organism or derivative or polypeptide derived therefrom or a combination thereof. In accordance with these embodiments, the at least one immunogenic agent or antigen or other agent can include, but is not limited to, one or more of: a viral antigen, a bacterial antigen, a toxin, a fungal agent or other pathogenic agent, a pharmaceutical agent (e.g., anti-cancer, anti-inflammatory or other agent) or a combination thereof. In some embodiments, the at least one immunogenic agent can also include, but is not limited to, a recombinant peptide, a recombinant protein, a peptide derived from a target protein or pathogen, a synthetic peptide or protein, a virus-like particle, a live virus, a live, attenuated virus, an inactivated virus, a bacterial antigen, a bacteriophage or phage or a combination thereof.

In some embodiments and further to paragraphs [0036]-[0060] above, each layer of the one or more outer coating layers can include at least one oxide agent. In certain embodiments, the one or more coating layers can include at least one of a metallo-organic material, metal oxides, metal alkoxides, and/or aluminum-based coating layer. In accordance with these embodiments, one or more outer coating layers can include, but is not limited to, one or more of aluminum oxide, an aluminum alkoxide (e.g., alucone), silicon dioxide (SiO₂), titanium dioxide (TiO₂), or silicon nitride (Si₃N₄) or zinc oxide (ZnO), alone or in a suitable combination composition. In some embodiments, one or more outer coating layers can include, but is not limited to, one or more of aluminum oxide, an aluminum alkoxide (e.g., alucone), silicon dioxide (SiO₂), titanium dioxide (TiO₂), or zinc oxide (ZnO), alone or in a suitable combination composition.

Yet other embodiments and further to paragraphs [0036]-[0061] above, provide for kits that can include one or more agitator, for example, a vibrator, and/or ultrasonic agitator disclosed herein and components for attaching or associating the agitator, such as an impactor, a vibrator, and/or ultrasonic agitator to a reactor system disclosed herein. In other embodiments, a kit can include tools for attaching the agitator(s), such as vibrator(s), impactor(s), or ultrasonic agitator(s) to a reactor vessel and optionally, include a collar and/or cuff and/or connector (e.g., screw or connector).

The instant application incorporates by reference PCT/US2017/019163, filed Feb. 23, 2017, in its entirety for all purposes.

Embodiments of the present disclosure and further to paragraphs [0036]-[0063] above, provide devices for improving the uniformity of coating microparticles and reducing agglomeration and adherence to surfaces of reactor systems disclosed herein. In other embodiments, the present disclosure provides for improving the uniformity of coating microparticles for single administration of a single composition capable of time-release of the coated agent in a subject. In accordance with these embodiments, systems for improving uniformity of these compositions can include one or more agitator(s), for example, vibrator(s), impactor(s), and/or ultrasonic agitator(s) associated with or coupled directly or indirectly to a reactor vessel contemplated herein for producing coated particles or microparticles containing one or more therapeutic agent.

In certain embodiments and further to paragraphs [0036]-[0064] above, agent-, antigen-, compound-containing particles or microparticles disclosed herein can use less agent, antigen or compound than used to formulate current pharmaceutical such as vaccines and other active agents (e.g., cost saving, agent sparing), and provide enhanced efficacy after a single administration with reduced cost for production and increased reliability and uniformity of compositions and further have reduced adherence or agglomeration further increasing benefits of these coated particles. In other embodiments, agent-, antigen-, compound-containing particles or microparticles provide for thermostable formulations that eliminate and/or reduce refrigeration requirements (e.g., cold chain refrigeration requirements), limit the concentrations of adverse agents (e.g., aluminum) administered to subjects, and increase compatibility.

Some embodiments disclosed herein and further to paragraphs [0036]-[0065] above, relate to methods of dehydration and formulation parameters, where these parameters can be adjusted in order to control nucleation rates, glass transition temperatures, and other material properties of the agent-, antigen-, and/or compound-containing particles or microparticles. In certain embodiments, dehydration can occur, for example, by lyophilization, vacuum-drying, spray drying, and/or spray-freeze-drying. In accordance with these embodiments, these particles or microparticles described herein are thermostable in order to tolerate the coating process with little to no degradation or loss of therapeutically active material. Using the device modifications disclosed herein, the resulting coated particles or microparticles have reduced adherence or agglomeration before, during or after the coating process.

In certain embodiments and further to paragraphs [0036]-[0066] above, pathogenic viruses or fragments derived thereof or modified viruses are contemplated of use in coated particles or microparticles disclosed herein. In accordance with these embodiments, the pathogenic viruses can include, but are not limited to, Ebola viruses or any filo viruses, a papovavirus (e.g., papillomaviruses, including human papilloma virus (HPV)), a herpesvirus (e.g., herpes simplex virus, varicella-zoster virus, bovine herpesvirus-1, cytomegalovirus), a poxvirus (e.g., smallpox virus), a reovirus (e.g., rotavirus), a parvovirus (e.g., parvovirus B19, canine parvovirus), a picornavirus (e.g., poliovirus, hepatitis A), a togavirus (e.g., rubella virus, alphaviruses such as Chikungunya virus), a hepadnavirus (e.g., hepatitis B virus), a flavivirus (e.g., dengue virus, hepatitis C virus, West Nile virus, yellow fever virus, Zika virus, other alphaviruses or flaviviruses, Japanese encephalitis virus), an orthomyxovirus (e.g., influenza A virus, influenza B virus, influenza C virus), a paramyxovirus (e.g., measles virus, mumps virus, respiratory syncytial virus, canine distemper virus, parainfluenza viruses), a rhabdovirus (e.g., rabies virus), a filovirus (e.g., Ebola virus), or a coronavirus or combinations thereof.

In some embodiments and further to paragraphs [0036]-[0066] above, an agent or antigen can include at least one bacteriophage or other similar agent. In accordance with these embodiments, a bacteriophage can be formulated in coated particles as disclosed herein. In other embodiments, one or more coated bacteriophages can be used to treat or prevent an infection or multi-drug resistant infection caused by one or more bacteria.

In other embodiments and further to paragraphs [0036]-[0066] above, at least one pathogenic agent can form part of a particle or microparticle disclosed herein or a polynucleotide or polypeptide derived therefrom. For example, these pathogenic agents or polynucleotides or polypeptides derived therefrom can include, a fungus, a prion, a bacterium or a toxin of a bacterium, including but not limited to, Pasteurella haemolytica, Clostridium difficile, Clostridium haemolyticum, Clostridium tetani, Corynebacterium diphtheria, Neorickettsia resticii, Streptococcus equi, Streptococcus pneumoniae, Salmonella spp., Chlamydia trachomatis, Bacillus anthracis, Yersinia spp., and Clostridium botulinum or combinations thereof. In yet other embodiments, the pathogenic agent contained in a microparticle can be a toxin, such as ricin toxin or botulinum toxin or a polynucleotide or polypeptide derived therefrom.

In some embodiments and further to paragraphs [0036]-[0066] above, the at least one pathogenic agent can be contained in a particle or microparticle disclosed herein or a polynucleotide or polypeptide derived therefrom. For example, these antigens can include, but are not limited to, Cryptococcus spp. (e.g., neoformans and gatti), Aspergillus spp. (e.g., fumigatus), Blastomyces spp. (e.g., dermatitidis), Candida albicans, Paracoccidioides spp. (e.g., brasiliensis), Sporothrix spp. (e.g., schenkii and brasiliensis), Histoplasma capsulatum, Pneumocystis jirovecii and Coccidioides immitis, or combinations thereof.

It will be recognized that the embodiments described herein can be applied to pharmaceutical compositions other than antigen or agent compositions disclosed herein. For example, small molecule drugs (e.g., anti-cancer agents), polynucleotide or siRNAs or carbohydrates or other agents and biologics can be similarly coated as disclosed for immunogenic agent-containing glassy microparticles described herein. The coating layers provide for a level of temporally controlled release desirable with certain pharmaceutical agents. The coating layers can serve to reduce exposure to moisture, reducing degradation. These coatings can function to protect water-soluble drug formulations or other moisture sensitive agents from degradation or dissolution until desired exposure to a subject after administration. Further, the embodiments can be used in applications outside of therapeutics. For example, coating layers can be applied to diagnostic markers. The coatings can allow delayed release of the marker, allowing sufficient trafficking/uptake time. This can be beneficial where the marker has a limited half-life. In certain embodiments, immunogenic compositions disclosed herein or encapsulated small molecules using layering/coating technologies described herein can be administered directly to an affected location of a subject such as the liver or kidney or brain depending on the ability of the deposited composition to remain in the targeted region.

In some embodiments and further to paragraphs [0036]-[0071] above, coated particles or microparticles having improved uniformity, reduced agglomeration and reduced adherence to the coating system due to having one or more agitator, for example, vibrator, impactor, and/or ultrasonic agitator can be used to manufacture one or more pharmaceutical composition of use to treat, reduce or prevent a health condition in a subject such as a human or other mammal or animal. In accordance with these embodiments, subject can be a dog (canine), a cat (feline), a horse (equine), cattle (bovine), a goat (hircine), a sheep (caprine), a pig (porcine) or poultry (e.g., chicken, turkey, duck, goose), or other bird, reptile, fish, or other animal.

In certain embodiments and further to paragraphs [0036]-[0072] above, agent-containing particles or microparticles described herein can include a single agent dose or two or more doses of a particular agent or different agents (e.g., prime and boost doses or combination agent formulations). In some embodiments, particles or microparticles can include doses for two or more different agents. In yet other embodiments, agent-containing particles or microparticles including doses of different agents can be combined into a mixture of agent-containing particles prior to coating or introduced on an outer layer for additional coating or as an outer layer on a coated microparticle. In certain embodiments, a mixture of agent-containing microparticles can be combined into a single administration for a reduced number of vaccine administrations.

In some embodiments and further to paragraphs [0036]-[0073] above, methods disclosed herein can concern controlled, ultra-rapid freezing rates and agitated coating processes. In accordance with these embodiments, antigen-, agent-, compound-containing microparticles or particles can include at least one polysaccharide, but are not limited to, trehalose or sucrose. In accordance with these embodiments, these agents can be used to generate glass-like matrices upon freezing. In certain embodiments, when the glass-forming agents are dried during a dehydration process (e.g., spray-drying) in the presence of one or more agents, these form powders (glassy microparticles), containing embedded agents. In this dehydrated state, protein physical and chemical degradation pathways, which require molecular motion, can be inhibited, as are other degradation pathways thereby stabilizing the agent in preparation for a coating process disclosed herein.

In some embodiments and further to paragraphs [0036]-[0074] above, buffers of use for formulations and compositions disclosed herein can include, but are not limited to, acetate, succinate, citrate, prolamine, histidine, borate, carbonate or phosphate buffer, or a combination thereof. In certain embodiments, a buffer can include one or more volatile salts of use in forming an agent-containing particles or microparticle in preparation for coating can include, but is not limited to, one or more of acetate, sodium succinate, potassium succinate, citrate, prolamine, arginine, glycine, histidine, borate, sodium phosphate, potassium phosphate, ammonium acetate, ammonium formate, ammonium carbonate, ammonium bicarbonate, triethylammonium acetate, triethylammonium formate, triethylammonium carbonate, trimethylamine acetate trimethylamine formate, trimethylamine carbonate, pyridinal acetate and pyridinal formate, or combinations thereof. In certain embodiments, the buffer can include histidine, for example, histidine-HCl. In some embodiments, polysaccharides and other agents of use to stabilize agents, antigens or compounds in preparation for coating by a device disclosed herein can include one or more of trehalose, sucrose, ficoll, dextran, sucrose, maltotriose, lactose, mannitol, hydroxyethyl starch, glycine, cyclodextrin, and povidone, or combinations thereof. In certain embodiments, the polysaccharide can be trehalose. In other embodiments, the polysaccharide concentration can be present in a weight-to-volume (w/v) concentration from about 0.1% to about 40% in a composition prior to dehydration or spray-drying; from about 1% to about 30% w/v; from about 5% to about 20%; or from about 8% to about 15% w/v in the composition prior to dehydration or spray-drying. In another embodiment, the polysaccharide can be a concentration from about 8% to about 11%; or about 9.5% w/v in the agent-, antigen- or compound-containing composition prior to dehydration or spray-drying.

In certain embodiments and further to paragraphs [0036]-[0075] above, a smoothing excipient of use in compositions and methods disclosed herein can be included in the composition to be lyophilized or spray-dried prior to coating of the particles or microparticles. In accordance with compositions disclosed herein, the smoothing excipient can aide in creation of a smooth(er) agent-containing particle or microparticle's surface, which in turn can create improved ability to deposit one or more covering layers on the particle or microparticle. In accordance with these embodiments, having a smooth(er) agent-containing glassy microparticle with reduced inconsistencies on the surface reduces the risk of cracking. In certain embodiments, coating layers described herein—each of which can be about 0.1 nm or thicker-can crack or incompletely cover the agent-containing particle or microparticle due to inconsistencies occurring on the surface of the underlying particle or microparticle creating raised or indented surfaces. In certain embodiments, the smoothing excipient can also function as a stabilizing agent. In some embodiments, the smoothing excipient can be hydroxyethyl starch or another pharmacologically acceptable plasma expander including, but not limited to, serum albumin, human serum albumin, dextran, hetastarch, and plasma protein factor, or the like or a combination thereof. In other embodiments, the smoothing excipient can be hydroxyethyl starch. In some embodiments, the smoothing excipient can be present in a weight-to-volume (w/v) concentration from about 0.1% to about 40% in a composition prior to dehydration or spray-drying. In some embodiments when the smoothing excipient is the same or different from the other stabilizing agent or polysaccharide, the smoothing excipient concentration is from about 0.1% to about 5%; about 0.1% to about 2.5%; about 0.1% to about 1.0%, about 0.1% to about 0.5%, or about 0.1% to about 0.25% in a composition prior to dehydration or spray-drying.

In certain embodiments and further to paragraphs [0036]-[0076] above, agents used in the thermostable agent-containing particles or microparticles of the present disclosure can be of use for prophylactic and/or therapeutic compositions. Suitability of agents for use in antigen-, compound- or agent-containing particles can be tested by reaction with antibodies or monoclonal antibodies which react or recognize conformational epitopes present on the intact target of the agent and based on the agent's ability to elicit the production of neutralizing antiserum. Suitable assays for determining whether neutralizing antibodies are produced are known to those of skill in the art. In this manner, in certain embodiments, it can be verified whether the immunogenic agents of the present disclosure will elicit production of neutralizing antibodies.

In some embodiment and further to paragraphs [0036]-[0077] above, systems disclosed herein having one or more agitators for at least reducing agglomeration and adhesion provide for more uniform syringability and uniform consistency of the compositions for a more reliable and predictable delivery and dosing of an agent, antigen or immunogenic agent disclosed herein. For example, agitation by one or more agitator, examples a vibrator, a pneumonic hammer, a solenoid hammer, or an ultrasonic agitator at the site of the reactor vessel can produce uniformly coated microparticles or particles for a more uniform composition with reduced loss from clumping between coated particles or coated microparticles and adherence to the reactor vessel.

In some embodiments and further to paragraphs [0036]-[0078] above, ALD or other layering or coating systems can be used to apply nanometer-thick coatings of inorganic, organic, or glass metallo-organic materials on the surface of antigen-, compound-, and/or agent-containing particles or microparticles with improved reliability due to intermittent or continuous agitation within the reactor vessel. In certain embodiments, the coating or sequestering layer can be a metal oxide or metal alkoxide or for example, an aluminum-based material including, for example, an aluminum oxide or an aluminum alkoxide (e.g., alucone). In accordance with these embodiments, the metal oxide or metal alkoxide (e.g., aluminum-containing material) is deposited on or applied to the surface of the one or more compound-, antigen- and/or agent-containing particle or microparticle to coat or sequester the one or more particles or microparticles in 1, 2, 3, 4, 5, 6, 7, 8, 9, 10, 11 to 100, to 200 to 300 to 400, to 500, to 600 or more layers of the metal oxide- or metal alkoxide- (e.g., aluminum) containing material to form encased particles or microparticles.

In certain embodiments and further to paragraphs [0036]-[0079] above, a binary reaction sequence can be used to deposit one or more layers of metal oxide or metal alkoxide (e.g., alumina) on an immunogenic agent-containing glassy microparticle. Antigen-, compound- and/or agent-containing particles or microparticles can be treated with alternating gas streams containing either metal oxide or metal alkoxide (e.g., trimethyl aluminum) or water vapor. In certain embodiments, the number of cycles can be varied to control formation of the coating or sequestering layer on the one or more particles or microparticles. In accordance with these embodiments, the one or more agitator(s), for example, ultrasonic agitator(s), vibrator(s), and/or pneumonic hammer(s) or solenoid hammer(s) can be cycled on and off for the reactor system in order to maintain consistent, more uniform coating layer coverage of the particles or microparticles with reduced adhesion, adherence and agglomeration of the particles or microparticles being coated.

In accordance with these embodiments and further to paragraphs [0036]-[0080] above, some advantages of depositing one or more coating layers on agent-containing particles or microparticles with improved uniformity include, but are not limited to, the coating layers can dissolve slowly or at a more accurate. Coordinated pre-determined rate when the agent-containing particles are administered to a subject, thus allowing temporal control of the release of the particle contents (e.g., the one or more antigens, agents or other compounds). Release times can be tailored by adjusting composition(s) of the coating layers and number and/or thickness of molecular layers applied to the agent-containing particles or microparticles. In some embodiments, about 5 to about 100 to about 150, to about 200, to about 300 to about 400 or more coating or sequestering layers can be used to form the coated or sequestered agent-containing particles microparticles of the present disclosure. In some embodiments, release of the agents from the coated or sequestered agent-containing particle's or microparticle's outer layers or core can occur within hours, to about 1 day, or about 7 days or about 30 days or about 60 days or about 90 days or about 120 days after administration to the subject. In some embodiments, release of the coated or sequestered agents from the particle can occur from up to about 10 days up to/and about 90 days up to/and about 120 up to/and about 150 up to/and about 180, up to/and about 210 or more days after administration to the subject depending on the number of coating layers and material of the coating layers. In some embodiments, release of the innermost agents can occur from about 10 days to about 21 days after administration to the subject. In some embodiments, release of the innermost agents can occur from about 14 days to about 21 days after administration to the subject. Further, in some embodiments, release of the innermost agents can occur from about 18 days to about 21 days after administration to the subject.

In certain embodiments and further to paragraphs [0036]-[0081] above, particle or microparticle size of the encased or fully coated one or more antigen-, compound-, agent-containing or combination agent-containing particles or microparticles can be from about 0.001 μm to about 150.0 μm, or about 0.05 μm to about 150.0 μm; or about 0.1 μm to about 150.0 μm; or about 0.2 μm to about 150.0 μm; or about 0.2 μm to about 100.0 μm; or about 0.2 μm to about 75.0 μm; or about 0.2 μm to about 50.0 μm. In other embodiments, an encased or fully coated one or more antigen-compound-, agent-containing or combination agent-containing particles or microparticles having multiple layers is less than about 5.0 μm in size. In certain embodiments, the particles or microparticles size prior to coating can be from about 1.0 μm to about 40.0 μm. It will be recognized that the elements of the antigen-, compound- and/or agent-containing particles or microparticles, coating layers, and any additional layers can be provided in concentrations capable of providing a suitable dose of a substance while maintaining an appropriate microparticle or particle size.

In certain embodiments and further to paragraphs [0036]-[0082] above, one advantage of using one or more aluminum-based materials as coating or sequestering layer(s) is that the aluminum-based materials can also act as an adjuvant. In accordance with these embodiments, the aluminum-based coating layers sequestering or surrounding the agent-containing particles and microparticles expose essentially the same surface chemistries to immunoactive cells as do standard aluminum-based adjuvant particles known in the art. In certain embodiments, the aluminum-based coating layer can be sufficiently thin so that the total aluminum concentration per administration of the composition to a subject is less than about 100 μg, less than about 50 μg, less than about 20 μg, less than about 10 μg, less than about 5 μg, or less than about 1.0 μg or even less.

In some embodiments and further to paragraphs [0036]-[0083] above, coating layers other than aluminum-based coating layers can be used in order to coat or sequester the agent containing particles or microparticles. In accordance with these embodiments, non-aluminum coating layers including, but not limited to, silicon dioxide (SiO₂), titanium dioxide (TiO₂), zinc oxide (ZnO), or other metal oxide or other alkoxide can be used either in combination with aluminum-based coating layers, or alone to the exclusion of aluminum-based coating layers or as a combination of non-aluminum coating layers such as a mixed layer of silicon dioxide (SiO₂), titanium dioxide (TiO₂), and/or zinc oxide (ZnO). In some embodiments, an agent-containing microparticle can be coated with one or more aluminum-based layers, followed by one or more layers of a different material. In certain embodiments, sequentially altering layers can be applied such as repeated application of for a predetermined number of Al₂O₃ layers, followed by the same or different number of TiO₂ layers (e.g., 5:5, 5:4, 10:10 or any other suitable alternating ratio) to reach the desired number of coating layers of a single or multiple layering material for coating a particle or microparticle disclosed herein. In accordance with these embodiments, different materials or repetitive layered structures formed from these materials can dissolve more slowly than the aluminum-based coating layer.

In other embodiments and further to paragraphs [0036]-[0084] above, one or more coating layers can be deposited on an agent- or antigen- or compound-containing particle or microparticle by, for example, atomic layer deposition (ALD, for example any instrumentation capable of atomic layer deposition can be used). ALD includes a thin film deposition technique that is based on the sequential use of a gas phase chemical process. ALD is considered a type of chemical vapor deposition. In certain methods, the majority of ALD reactions use two chemicals, referred to as precursors. These precursors react with the surface of a material one at a time in a sequential, self-limiting, or directed manner. Through the repeated exposure to separate precursors, a thin film can be deposited. Use of a reactor system for example, ALD to deposit coating layers on antigen-, compound-, agent-containing particles or microparticles can be based on sequential, self-limiting reactions and provides for layer thickness control at the Angstrom level and tunable coating layer composition. Examples of ALD procedures of use in methods disclosed herein for depositing coating or sequestering layers on agent-containing microparticles or particles can be found for example in LF Hakim et al, Adv Funct Mater, 2007 November; 17 (16): 3175-81, DM King et al., Powder Technol, 2012 Can;221:13-25, and X Liang et al., ACS Appl Mater Interfaces, 2009 September (web); 1 (9): 1988-95, each of which is hereby incorporated by reference in their entirety.

Embodiments of the present disclosure and further to paragraphs [0036]-[0085] above, can include polypeptides, polynucleotides, carbohydrates, proteins, virus-like particles, inactivated or attenuated pathogens (e.g., live, attenuated viruses), or other antigens or agents that elicit a therapeutic response when introduced to a subject. In accordance with these embodiments, an elicited response can be a prophylactic response, reducing or preventing infection, disease, or toxicity induced by exposure to a pathogen including, but not limited to, a virus, bacteria, or fungus, or toxin, and/or can be therapeutic, reducing the severity, preventing, or treating an infection, disease, other health condition, or toxicity.

In certain embodiments and further to paragraphs [0036]-[0086] above, compositions, systems, methods, devices and uses disclosed herein concern using a particle or microparticle coating system having a fluidized bed in combination with other devices to induce additional reactor system agitation, for example, impacting, vibration, or ultrasonic agitation for preventing, reducing, or eliminating agglomeration and/or adherence of nanoparticles, microparticles, particles, coated nanoparticles, coated microparticles or coated particles disclosed herein. Fluidization of a system contemplated herein uses a gas stream to agitate a powder bed containing particles or microparticles for coating in the system. The fluidized bed formed by the gas stream can be present during purge phases (e.g., purge gas such as argon only flowing through the system), and during application of precursors, which can be flowed through the system by the flow of the purge gas. As such, the systems and methods described herein utilize agitation in the form of ultrasonic agitation, mechanical vibration, and impacting to assure adequate mixing and contact of the chemical reactants with individual particles for improved coating with reduced adherence and agglomeration.

Other embodiments provide kits of use with the apparatus, system, methods, and compositions described in the present disclosure. In certain embodiments, a kit can include an agitator, for example, an ultrasonic agitator, impacting, or vibrating device, with components such as a sleeve and/or connector for attaching the device to a reactor vessel of a coating system.

In other embodiments, kits are contemplated of use for compositions, and methods described herein. Kits can be portable for storage and transport of systems and components disclosed herein. In certain embodiments, kits can include a single or multiple agitating devices for attaching to a reactor system contemplated herein.

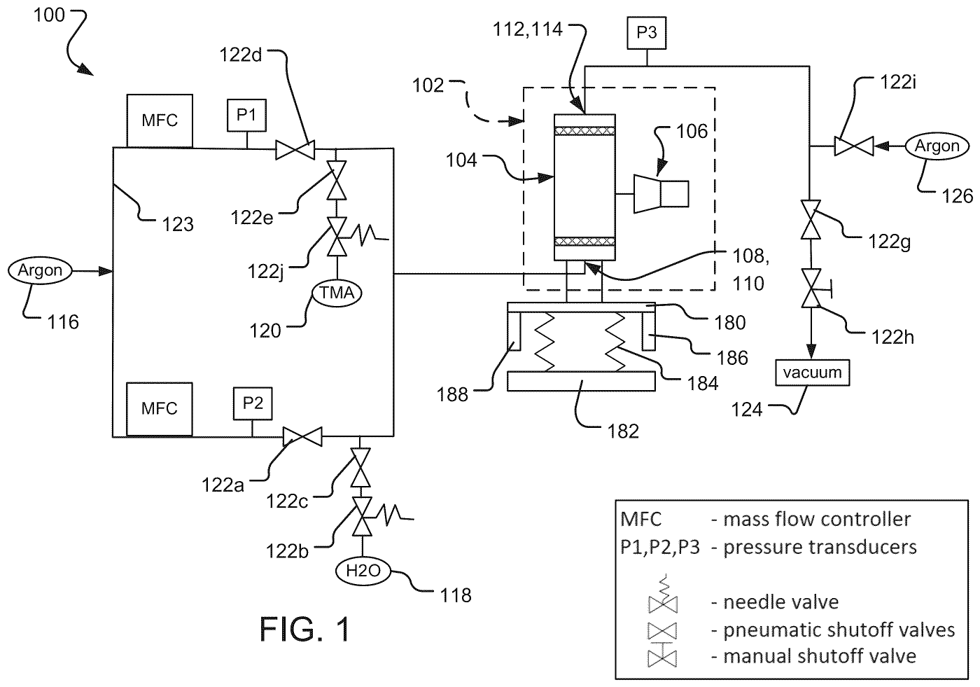

In other embodiments, and as illustrated in FIG. 1, an ALD system 100 includes a reactor system 102 including a reactor vessel 104 and an agitator or sonicator 106 (e.g., an ultrasonic agitator) coupled to the reactor vessel 104. The ALD system 100 facilitates coating of microparticles within the reactor vessel 104 and the agitator 106 delivers or transfers mechanical oscillations or vibrations (e.g., through acoustic wave also referred to as sound waves) to the reactor vessel 104 to reduce or prevent the microparticles from agglomerating or adhering to the interior walls of the reactor vessel 104. As seen in FIG. 1, the ALD system 100 further includes an inlet opening 108 at an inlet end 110 of the reactor vessel 104 for delivering of gases into the reactor vessel 104.

The ALD system 100 further includes an outlet opening 112 at the outlet end 114 of the reactor vessel 104 for exhausting gases from the reactor vessel 104. Various vessels are in fluid communication with the inlet opening 108 including for example, a purge gas vessel 116 (e.g., Ar, argon vessel), a precursor B vessel 118 (e.g., H₂O vessel), and/or a precursor A vessel 120 (e.g., trimethylaluminium (TMA) vessel). In some embodiments, certain examples of precursor A include, but are not limited to, Trimethylaluminum, Dimethylzinc, Diethylzinc, Titanium Tetrachloride, or the like and similar ALD precursors or other precursors. In certain embodiments, examples of precursor B can include but are not limited to, water, ozone, alcohols, or the like. In some embodiments, purge gas (e.g., argon) can be used as a fluidization gas to maintain a fluidized particle bed during applications of Precursor B (e.g., water vapor) and Precursor A (e.g., TMA). The purge gas vessel 116 can be a compressed gas cylinder containing purge gas. It can include a flow modulating device controlling the flow therefrom. Additionally, argon can be used as a purge gas (e.g., delivered without any other substances) between applications of precursor A and precursor B as described below. Purge gas can also be used to dry the particles and to assist in the dislodgment of adhered and/or agglomerated microparticles to each other and to the walls and filters of the reactor vessel 104. As illustrated in FIG. 1, the ALD system 100 can further include various valves, mass flow controllers, and pressure transducers to control the flow and delivery of the purge gas (e.g., argon), precursor B (e.g., water), and precursor A (e.g., TMA) into the reactor vessel 104. It is noted that while argon can be used as a process gas herein, other inert gases such as nitrogen or helium can be used.

On an inlet side of the reactor vessel 104, the following valves 122 are present. Between the purge gas (e.g., argon) vessel 116 and the precursor B (e.g., H₂O) vessel 118 is a first valve 122a. The control of precursor B (e.g., water) into the conduit 123 is controlled by a second valve 122b (needle valve) and a third valve 122c. When all valves are at least partially open, purge gas flows from the purge gas vessel 116 through the conduit 123 and pulls precursor B (e.g., water vapor) from the vessel 118 into the conduit 123 according to the actuation of the needle valve of the second valve 122b. In some embodiments, as illustrated in FIG. 1, between the purge gas vessel 116 and the precursor A (e.g., trimethylaluminium (TMA)) vessel 120 can be a fourth valve 122d, a fifth valve 122c, and a tenth valve 122j (needle valve). When these valves are at least partially open (and when the second and third valves 122b, 122c are closed), purge gas flows from the purge gas vessel 116 through the conduit 123 and pulls precursor A (e.g., TMA) from the precursor A (e.g., trimethylaluminium (TMA)) vessel 120 into the conduit 123 towards the reactor vessel 104. The reaction vessel 104 can be backflushed by flowing purge gas (e.g., argon) in an opposite direction through the reaction vessel 104 by briefly opening valve 122j while all other valves 122a, 122c, 122d, 122e, 122g, and 122h are closed; for example, to remove build-up (e.g., adherence and/or agglomeration) in the reactor. In accordance with these embodiments, the valve is opened but the reaction chamber is not opened therefore, reducing chance of contamination of the particles being coated and other concerns with opening the reaction chamber during this time of processing.

In fluid communication with the outlet opening 112 is a vacuum 124 and a purge gas vessel 126 (e.g., argon) in fluid communication with the conduit 123, as well as various pressure transducers. It is noted that the purge gas vessel 126 can be the same purge gas vessel 116 in fluid communication with the inlet opening 108. In such an instance, the valves and control system will simply control the delivery from a single vessel to either the inlet side or the outlet side. A seventh valve 122g and an eighth valve 122h (manual shutoff valve) lead to the vacuum 124. A ninth valve 122i controls the flow of purge gas from the purge gas vessel 126 into the conduit. In some embodiments, as illustrated in FIG. 1, the ninth valve 122i can be briefly opened with the valves 122d, 122e, 122a, and 122c on the inlet side of the reaction vessel 104 closed, and the seventh and eighth valves 122g, 122h of the vacuum closed, which causes purge gas to flow back through the reaction vessel 104 for backflushing purposes. In these examples, the backflush of purge gas through the reaction vessel 104 can cause build-up of particles on the outlet filter of the reaction vessel 104 to dislodge therefrom. In accordance with certain embodiments, the valve is opened but the reaction chamber is not opened therefore, reducing chance of contamination of the particles being coated. It is noted that this process does not involve the reaction chamber housing the particles being coated and is not a sieving process and microparticle and/or particles are not removed from the system and are clearly not removed and reintroduced to the system.

It is noted that while the reactor system 102 is described and shown relative to an ALD system 100, the reactor system 102 and disclosed herein can be incorporated into other systems that utilize vapor phase coating techniques such as chemical vapor deposition (CVD), molecular layer deposition (MLD), or physical vapor deposition (PVD) or other similar depositions.

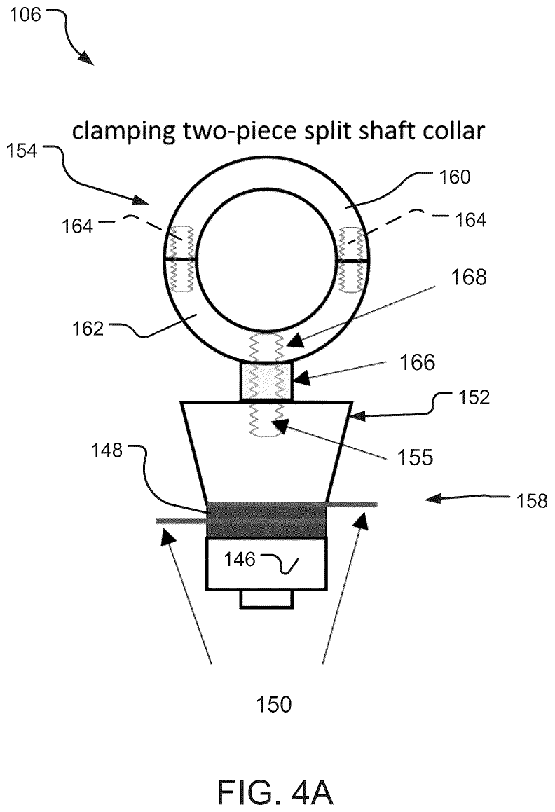

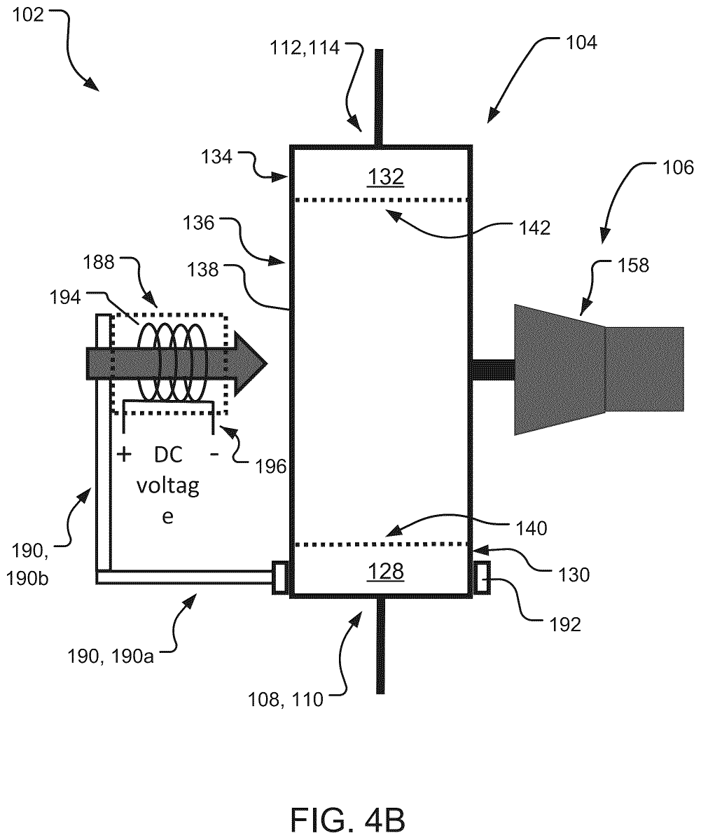

Still referring to FIG. 1, the reactor vessel 104 is coupled to a reactor mount 180, which is in turn supported by a surface 182, such as a table, via one or more resilient members 184 such as a spring or rubber mount. A vibrating motor 186 (e.g., motor with offset weight) is coupled to the reactor mount 180 such that, when actuated, the motor 186 vibrates the reactor mount 180, which transmits the vibrations into the reactor vessel 104. The vibrating motor can operate at low-frequencies such as less than 300 Hz. In some examples, the vibrating motor 186 can be an electric motor with a speed of approximately 3200 revolution per minute (RPM). In some examples, the vibrating motor 186 can be an electric motor with a speed of approximately 3200 vibrations per minute (VPM). An impactor 188 (e.g., pneumatic or solenoid hammer) is coupled to the reactor mount 180 such that, when actuated, the impactor 188 impacts the reactor mount 180, which transmits vibration into the reactor vessel 104. The impactor 188 can operate within a frequency range of about 0.5 to about 10 Hz. In other embodiments, the impactor can also be mounted directly to the reactor vessel, for example, with a mounting bracket (see for example, FIG. 4B, or mounted to the reactor housing or equipment-bearing table, to provide a more direct impact by striking the reactor vessel instead of the reactor support or by perpetuating a vibration through a mounting arm to the vessel, for example. The impactor 188 can be pneumatic hammer. For example, the pneumatic hammer can be an interval impactor that generates individual blows or impacts to the system (similar to a hammer). In some embodiments, the impactor 188 can generate an impact force between approximately 0.5 lbs and 1.5 lbs with each impact. In some examples, the impactor 188 can generate an impact force between approximately 0.75 lbs and 1.25 lbs. In some examples, the impactor 188 can generate an impact force between approximately 0.9 lbs and 1.1 lbs. In some examples, the impactor 188 can generate an impact force of approximately 0.95 lbs. The impactor 188 can be a solenoid hammer (e.g., a solenoid push-pull device). In other embodiments, the impactor 188 can include one or more of the following approximate specifications: a DC, 24V, 25N, Push Pull Type Solenoid Electromagnet, 0.4 A, 9.6 W, 10 mm Stroke, Open Frame, Linear Motion.

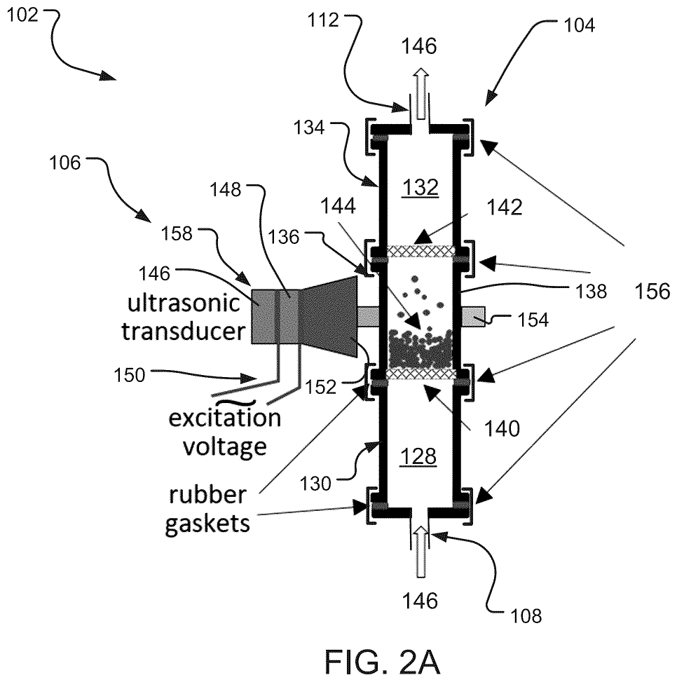

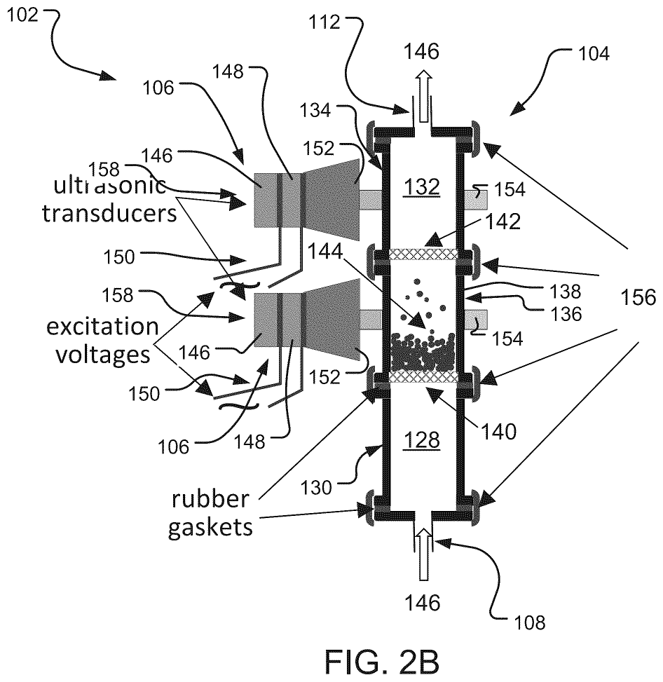

As illustrated in FIGS. 2A and 2B, examples of a reactor system 102 is provided in a side cross-sectional view. The reactor vessel 104 extends between the inlet opening 108 and the outlet opening 112. The reactor vessel 104 can include an inlet section 128 defined by one or more sidewalls 130 and in fluid communication with the inlet opening 108. The reactor vessel 104 can also include an outlet section 132 defined by one or more sidewalls 134 and in fluid communication with the outlet opening 112. The one or more sidewalls 130, 134 can be a cylindrical tube, cube, or pipe. The reactor vessel 104 can further include a processing chamber 136 positioned between the inlet section 128 and the outlet section 132. The processing chamber 136 includes chamber walls 138 having inner and outer surfaces. The processing chamber 136 is coupled to the one or more sidewalls 130 of the inlet section 128 and further coupled to the one or more sidewalls 134 of the outlet section 132. The processing chamber 136 includes an inlet filter 140 adjacent the inlet section 128 of the reactor vessel 104 and an outlet filter 142 adjacent the outlet section 132 of the reactor vessel 104. The inlet and outlet filters 140, 142 can act as a microparticle or nanoparticle barrier, but not as a sieve. Process gases can flow through the filters 140, 142, but microparticles or nanoparticles are retained between the two filters 140, 142. In certain embodiments, the inlet and outlet filters 140, 142 (also referred to as a “frit”, “frit disk” or “frit disk filter”) can be, for example, sintered stainless steel filters that can be sized to retain the microparticles or nanoparticles between the inlet and outlet filters 140, 142. In certain embodiments, the inlet and outlet filters 140, 142 can be 10 micro frit disk filters or other suitable size to maintain the microparticles or nanoparticles within the reaction chamber for optimal retention and coating. The processing chamber 136 can be removably coupled to the inlet and outlet sections 128, 132 of the reactor vessel 104. In certain instances, the processing chamber 136 can be removably coupled to the inlet and outlet sections 128, 132 of the reactor vessel 104 via clamp fittings 156. Rubber or other suitable gaskets can be utilized to provide hermetic sealing between the inlet section 128, outlet section 132, and the processing chamber 130. The clamp fittings 156 can be made of a metal that will be in intimate contact with the reactor walls when tightened and thus can transfer vibrations from the process chamber 136 to the outlet section 132 that contains the outlet filter 142 causing the outlet filter 142 to vibrate along with the outlet section 132. In other embodiments, more than one transducer can be mounted or affixed to different parts of the reactor assembly to provide additional vibration or additional vibration coordination of the reactor system. In another embodiment, one or more transducers can be mounted directly to a reactor system, for example using a screw or other component, for example, using a weld-on screw. In certain embodiments, as illustrated in exemplary FIG. 2B, two transducers can be associated with a reactor system disclosed herein or in direct communication with a reactor vessel or reaction chamber of a system contemplated herein.

In some embodiments, as illustrated for example in FIG. 2A, one transducer 158 can be mounted or affixed to different parts of the reactor vessel 104 (e.g., the processing chamber 136) to provide additional vibration or additional vibration coordination of the reactor system 102. In other embodiments, as illustrated for example in FIG. 2B, more than one transducer 158 (e.g., two transducers 158) can be mounted or affixed to different parts of the reactor vessel 104 (e.g., the inlet section 128, processing chamber 136, outlet section 132) to provide additional vibration or additional vibration coordination of the reactor system 102. In another embodiment, one or more transducers 158 can be mounted directly to a reactor system 102, for example using a screw or other component, for example, using a weld-on screw. In certain embodiments, as illustrated in exemplary FIG. 2B, two transducers 158 can be associated with a reactor system 102 disclosed herein or in direct communication with a reactor vessel 104 or processing chamber 136 of a system 102 contemplated herein.

In another aspect of the disclosure, the chamber walls 138 of the processing chamber 136 define an internal volume of the reactor vessel 104. As seen in FIGS. 2A-2B, the microparticles 144 to be coated or being coated are located within the processing chamber 136 of the reaction vessel 140. One or more process gases 146 are introduced to the inlet opening 108 of the reactor vessel 104, thereby fluidizing the microparticles within the processing chamber 136 (e.g., fluid bed). The one or more process gases 146 pass through the processing chamber 136 and exits the reactor vessel 104 at the outlet opening 112.

As illustrated in FIG. 2A, the reactor system 102 includes an agitator 106 (e.g., ultrasonic agitator) coupled to the processing chamber 136 of the reactor vessel 104. In the embodiment illustrated in FIG. 2A, the agitator 106 includes a sonicator or ultrasonic transducer 158. The ultrasound transducer 158 includes an end cap 146, one or more piezoelectric plates 148, electrodes 150, and a radiation head 152. The components can be coupled together via a screw or other coupling component (not shown in FIG. 2A). When an oscillating voltage is applied to the electrodes 150, the piezoelectric plates 148 vibrate and generate acoustic energy, such as ultrasound energy (>20 kHz). Stated differently, the ultrasound transducer 158 converts electrical energy to acoustic energy, which can reach ultrasonic ranges, in the form of acoustic or sound waves. The piezoelectric plates 148 change size and shape when the voltage is applied. As an example, when AC voltage is applied, the piezoelectric plates 148 oscillate and produce ultrasound energy accordingly. The ultrasound energy is transmitted through the radiation head 152 to a wave propagating structure 154, such as a clamp collar, which is affixed to the processing chamber 136. In this configuration, the ultrasound energy from the ultrasound transducer 158 is transmitted through the clamp collar 154 to the processing chamber 136 to inhibit the agglomeration of microparticles on the inner surfaces of the chamber walls 138. In certain instances, the ultrasonic transducer 158 can be a 40 kHz 60 W transducer. For example, the ultrasonic transducer 158 can be a YaeCCC (used at for example, 60 W 40 KHz/60 W) Ultrasonic Cleaning Transducer Cleaner or similar or substitutable device known in the art. The control board for the ultrasonic transducer can be, for example, a Power Driver Board 110V AC or other suitable control board.

As illustrated in FIG. 2B, the reactor system 102 can include more than one agitator 106 (e.g., ultrasonic agitator), for example two agitators 106 or more, coupled to the reactor vessel 104. In accordance with this embodiment illustrated in FIG. 2A, two agitators 106 can include a sonicator and/or ultrasonic transducer 158. Each ultrasonic transducer 158 (in FIG. 2B) illustrated here can have the same or similar characteristics as the ultrasonic transducer 158 (in FIG. 2A) previously presented. Ultrasound energy generated from each ultrasound transducer 158 can be transmitted through each respective collar 154 associated with the reactor vessel 104 (e.g., processing chamber 136, outlet section 132). Although FIG. 2B illustrates a first ultrasonic transducer 158 coupled to the processing chamber 136 and a second ultrasonic transducer 158 coupled to the outlet section 132, the two or more ultrasonic transducers 158 can be coupled to the reactor vessel 104 (e.g., the inlet section 128, processing chamber 136, outlet section 132) or in any other logical configuration and at various locations without departing from the scope of this disclosure. It is contemplated that 2 transducers are not a required feature but an alternative feature where one transducer or more than 2 transducers are also contemplated.

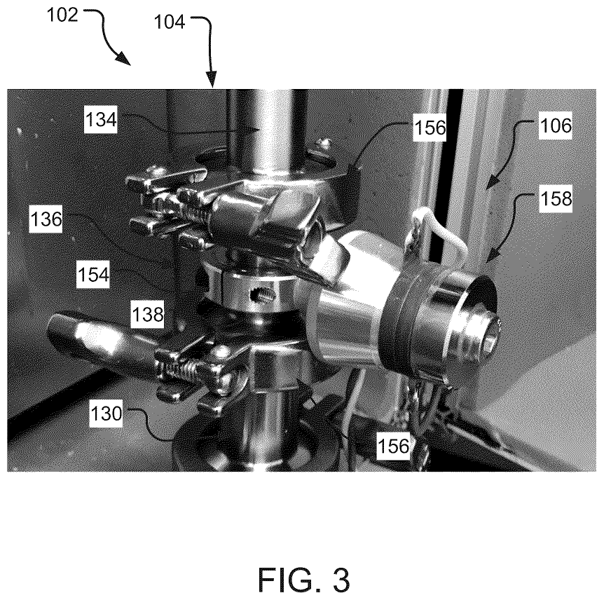

FIG. 3 illustrates a perspective view of the reactor system 102 having an agitator 106 (e.g., ultrasonic agitator) directly linked to the processing chamber 136 of the reactor vessel 104. In addition, this illustrated embodiment depicts the processing chamber 136 is removably coupled with the inlet section 130 and the outlet section 134 via metal clamps 156 and hermetically sealed with elastomer gaskets. The claims 156 aid in transferring the ultrasonic energy to the inlet and outlet sections 130, 134 of the reactor vessel 104.

FIG. 4A illustrates a top view of the agitator 106 (e.g., ultrasonic agitator) including the ultrasound transducer 158 and the wave propagating structure 154 in the form of a two-piece split shaft collar. The structure 154 includes first and second arcuate sections 160, 162 forming a collar that are releasably coupled together via threaded members 164, alternate fastening devices are contemplated herein. A spacer 166 and internal threaded member 168 couples the collar to a radiation head of the ultrasound transducer 158.

In certain embodiments, the shaft collar can be a set screw style collar or a clamping style collar. The shaft collar can be an axial clamp. In some embodiments, the shaft collar can be a single-piece collar or a two-piece collar. The single-piece collar can include a single-piece collar with a set screw or a single-piece clamp style collar with an integrated screw. The two-piece collar can include a two-piece collar with a set screw or a two-piece clamp style collar. The collar can be hinged. The collar can be threaded or keyed. The collar can be mountable. The collar can contain a hex or d-bore profile. The collar can include a quick clamping and/or quick release mechanism.

The shaft collar can be made of metallic or non-metallic materials. In accordance with these embodiments, a metallic collar can be made of aluminum, steel, stainless steel, coated alloyed steel, or titanium. The alloyed steel can be coated with zinc, chromium, or black oxide or other suitable material. In other embodiments, a non-metallic material can include an engineered plastic material. In certain embodiments, the shaft collar can be made of a nylon material.

As illustrated in FIG. 4A, the radiation head 152 includes a threaded bore 155 that receives the threaded member 168 which couples the collar, the stem 166, and the radiation head 152 together. In another embodiment, the threaded member 168 can be directly coupled (e.g., welded) to the processing chamber 136 of the reactor vessel 104. In this way, the radiation head 152 can be releasably coupled to the processing chamber 136 via threading the radiation head 152 to the threaded member 168. In accordance with this embodiment, the sonicator 158 (e.g., ultrasonic transducer) delivers acoustic waves to the processing chamber through the threaded member 168.

FIG. 4B illustrates a schematic of an impactor 188 (e.g., pneumatic or solenoid hammer) associated with a reactor system 102 in accordance with certain embodiments disclosed herein. The impactor 188 illustrated in FIG. 4B can have one or more same or similar elements or features as the impactor 188 illustrated in FIG. 1 as previously disclosed. The impactor 188 can transfer energy, directly or indirectly, to the reactor vessel 104. When actuated, the impactor 188 can inhibit the agglomeration of particles or microparticles on the inner surfaces of the chamber walls 138 or filters or other features of the processing chamber 136 of the reactor vessel 104. In some embodiments, the impactor 188 can be mounted to various components of the reactor system 102. In some examples, as illustrated for example in FIG. 1 and as disclosed herein, an impactor 188 can be mounted to a reactor mount 180. When actuated, the impactor 188 can impact the reactor mount 180, which can transmit vibration to the reactor vessel 104. In certain examples, as illustrated in FIG. 4B, an impactor 188 can be mounted directly to the reactor vessel 104. When actuated, the impactor 188 can transmit vibration into the reactor vessel 104 though a coupling structure 192 and/or the impactor 188 can directly impact the reactor vessel 104 to cause vibration in the reactor vessel 104.

As illustrated in FIG. 4B, the impactor 188 can be coupled to the reactor vessel 104 (e.g., the inlet section 128) with one or more members 190 (e.g., a bracket) and/or a coupling structure 192. The coupling structure 192 (as illustrated in FIG. 4B), which can couple the impactor 188 to the reactor vessel 104, can have one or more same or similar elements or features as the wave propagation structure 154 (as illustrated in FIGS. 2A-2B, FIG. 3, FIG. 4A), which can couple the agitator 106 (e.g., ultrasonic agitator or ultrasonicator or the like) to the reactor vessel 104. For example, the coupling structure 192 can be a clamp collar (e.g., a two-piece split shaft collar) or other suitable coupling element.

In other embodiments, the one or more members 190 (e.g., 190a, 190b) can be clamped to the reactor vessel 104 (e.g., clamped to the reactor vessel 104 by the coupling structure 192). In one embodiment, the one or more members 190 can extend from the coupling structure 192 to the impactor 188. In some embodiments, one end of the members 190 can be connected to the coupling structure 192 (which can be coupled to the reactor vessel 104) and the opposite end of the members 190 can be connected to the impactor 188. In some examples, the coupling structure 192 includes a first member 190a extending outward (e.g., substantially horizontally) from the coupling structure 192 and a second member 190b extending (e.g., substantially vertically) from the first member 190a to the impactor 188. For example, the one or more members 190 can be a bracket that connects the impactor 188 and the coupling structure 192. In some embodiments, the impactor 188 can be oriented substantially perpendicular to the longitudinal axis of the reactor vessel 104 such that, when actuated, the impactor 188 actuates along an axis that is substantially perpendicular to the reactor vessel 104. For example, the impactor 188 can impact the reactor vessel 104 along an axis that is substantially perpendicular to the longitudinal axis of the reactor vessel 104.

Continuing with FIG. 4B, the impactor 188, when actuated, can directly impact the reactor vessel 104 (e.g., processing chamber 136). Although FIG. 4B illustrates the impactor 188 oriented to impact the processing chamber 136 of the reactor vessel, the impactor 188 can be oriented to impact other locations on the reactor vessel 104 (e.g., the inlet section 128, processing chamber 136, outlet section 132) without departing from the scope of this disclosure.

In certain embodiment, the impactor 188, when actuated, can transmit vibration through the coupling structure 192 (e.g., through the one or more members 190 and the coupling structure 192 which is affixed to the reactor vessel 104) to the reactor vessel 104 (e.g., processing chamber 136). Although FIG. 4B illustrates the coupling structure 192 coupled to the inlet section 128 of the reactor vessel 104, the coupling structure 192 can be coupled to other locations on the reactor vessel 104 (e.g., the inlet section 128, processing chamber 136, outlet section 132) without departing from the scope of this disclosure.

In some embodiments, the impactor 188 can operate within a frequency range of about 0.5 to about 10 Hz. In one embodiment illustrated in FIG. 4B, the impactor 188 is a solenoid impactor. For example, the solenoid impactor can include an electric coil 194 (e.g., a solenoid). When an actuation voltage is applied to the electrodes 194, the impactor 188 actuates and generates energy. Stated differently, the impactor 188 converts electrical energy to energy (e.g., mechanical energy, ultrasound energy). As an example, when DC voltage is applied, the impactor 188 actuates and produces energy accordingly.

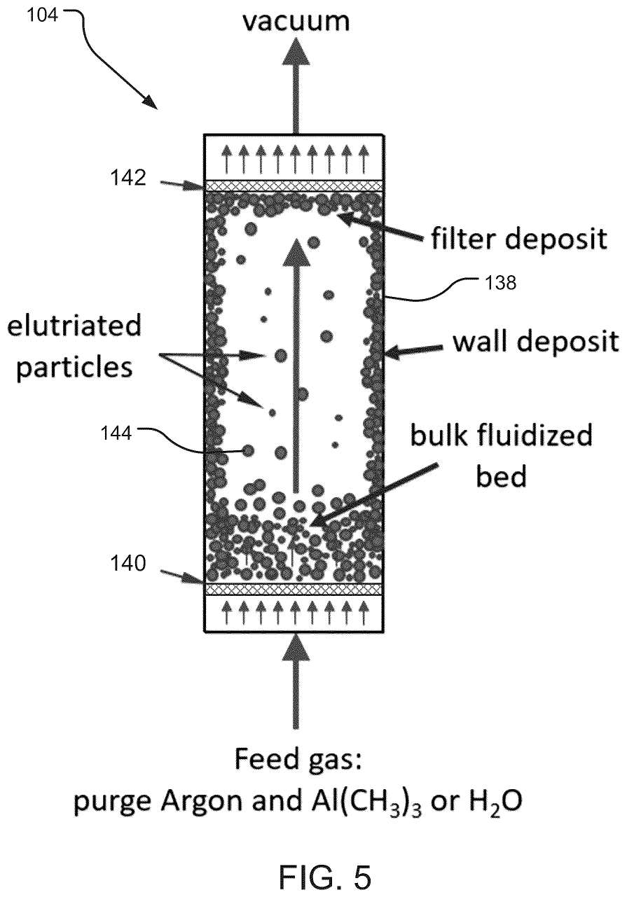

FIG. 5 illustrates a side cross-sectional view of the processing chamber 136 of the reactor vessel 104 without one or more agitators (e.g., sonicator, impactor, vibrator) as part of the reactor system. As illustrated in this figure, the microparticles 144 are contained in the processing chamber 136 via the chamber walls 138, the inlet filter 140, and the outlet filter 142. Without the agitator(s), the microparticles 144 can deposit on the surface, or adhere to the chamber walls 138 and can agglomerate to one another. Similarly, the particles 144 can deposit on the surface of, or adhere to the inlet and outlet filters 140, 142 and agglomerate to one another. As disclosed herein, agglomeration of microparticles reduces the efficacy and product outcome of the ALD system and process for coating particles or microparticles and causes significant product loss as well as product inferiority such as lack of uniformity.

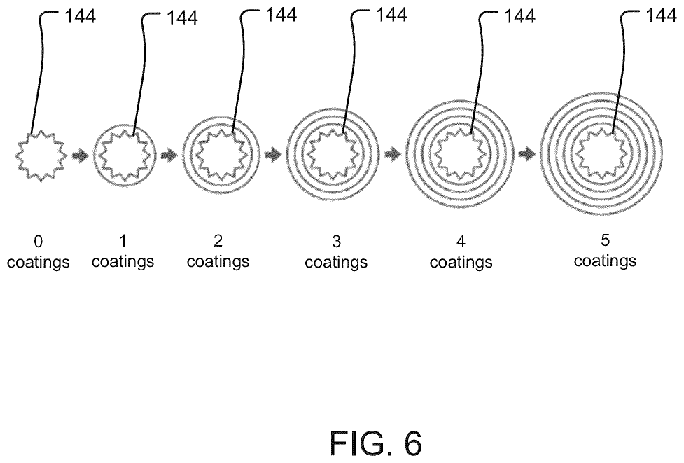

Embodiments disclosed herein solve issues regarding microparticle coating processes with respect to agglomeration and chamber adherence. It is desirable to coat microparticles with coating layers or films that encase the immunogenic agent-containing microparticles or antigen-containing or agent-containing microparticles where the coating layers are uniform and, thus, readily and predictably dissolvable in a subject once administered to expose the immunogenic agent, or antigen or agent to the subject to prevent, reduce or treat a condition. Such uniform coating layers are illustrated in FIG. 6, which illustrates successive coating processes on a microparticle 144. Starting from the left, the microparticle has not undergone any coating processes but is in a thermostable form (e.g., glassy particle or glassy microparticle or other thermostable form). Moving to the right, the microparticle has been coated, one time, two times, three times, four times, and five times etc. as indicated by the successive number of layers surrounding the microparticle 144. In certain embodiments, systems and methods disclosed herein provide for production of more uniformly coated particles with reduced loss and reduced side effects of adherence and agglomeration leading to an increase in production, a more reliable end-product, improved syringability and reduce costs in production. In some embodiments, up to 10, up to 50, up to 100, up to 150, up to 200, up to 250, up to 300, up to 350, up to 400 or more coatings can be applied to microparticles disclosed herein using devices described in the instant disclosure without the need to open up the reactor vessel and remove adhered or agglomerated microparticles or particles. It is noted that FIG. 6 illustrates a coating process. In an ALD process, it can take a single or multiple rounds or cycles of processing to complete a single coat since the coatings are very thin. One ALD cycle can apply a 0.1-0.2 nanometer coating on about a 1.0 micron particle or microparticle. In this example, 100 cycles of an ALD process can yield a coat that is about 0.02 microns thick. This can account for only about 1-2% of the total diameter of the particle.

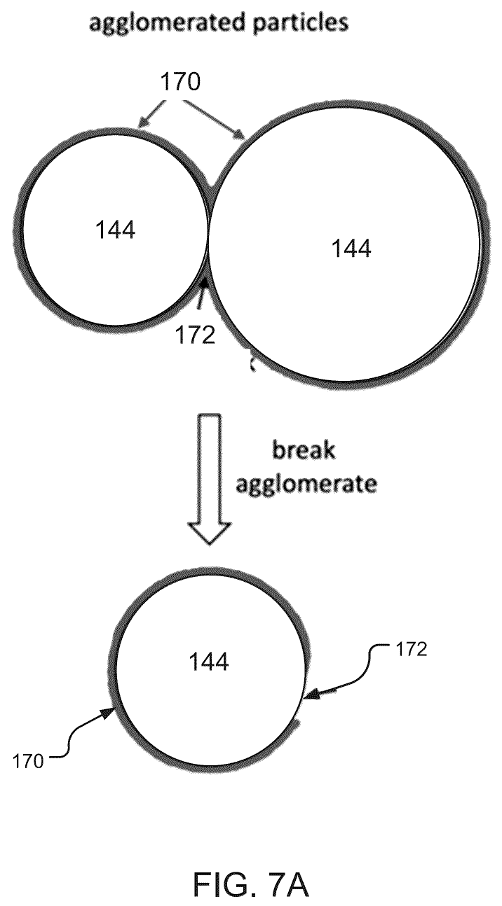

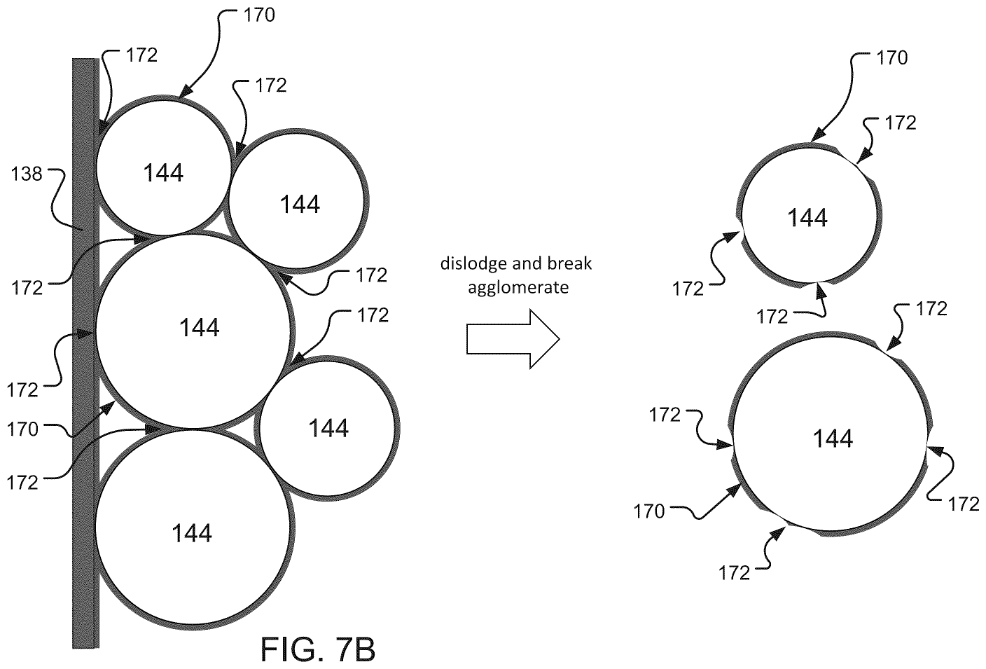

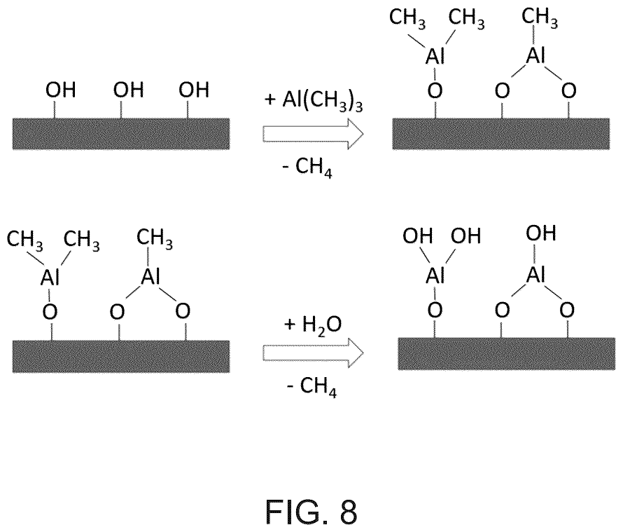

When microparticles or particles disclosed herein are subjected to a coating process such as an ALD coating process having excessive agglomeration of microparticles or particles as illustrated in FIG. 5, the microparticles or particles can become unevenly coated, adhere to surfaces, and can adhere to one another and, in some instances, form defective particles with thin or no coating forming holes in certain regions. FIG. 7A is a schematic illustrating how agglomerated particles 144 (as illustrated on the top side of the figure) can cause defective coatings in coated particles 144 (as illustrated on the bottom side of the figure). For example, particles 144 can agglomerate by adhering to each other (e.g., particles 144 adhering to other particles 144), as illustrated on the top side of FIG. 7A. FIG. 7B is a schematic diagram illustrating how agglomerated particles 144 and/or adhesion of particles 144 (as illustrated on the left side of the figure) can cause defective coatings in coated particles 144 (as illustrated on the right side of the figure). For example, particles 144 can agglomerate by adhering to (e.g., attaching to) the chamber wall 138 or other structures within a reaction chamber such as filters, as illustrated on the left side of FIG. 7B. The chamber wall 138 (as illustrated in FIG. 7B) can be the chamber wall 138 of the processing chamber 136 of the reactor vessel 104 (as illustrated for example in FIGS. 1-2B and FIG. 4B). As another example, particles 144 can agglomerate by adhering to each other (e.g., particles 144 adhering to other particles 144).

Unevenly coated or agglomerated particles are illustrated in FIGS. 7A-7B. As illustrated in these figures, as particles 144 agglomerate (e.g., adhere to the chamber wall 138, adhere to other particles 144), the ALD layers 170 do not coat the contact area 172 (e.g., where particles 144 adhere to the chamber wall 138, where particles 144 adhere to other particles 144) or unevenly coat these areas between the agglomerated particles 144. In FIG. 7A for example, when the agglomerated microparticles 144 dislodge from each other, the former contact area 172 is less coated (as illustrated on the bottom side of the figure) than the other portions of the microparticle 144 in which have an ALD layer 170. In FIG. 7B for example, when the agglomerated microparticles 144 dislodge from the chamber wall 138 and/or dislodge each other, the former contact area 172 is less coated (as illustrated on the right side of the figure) than the other portions of the particle or microparticle 144 having an ALD layer 170. In certain cases, this uneven coating of the microparticles or particles 144 can lead to uneven coating and to inconsistent rates of dissolution of the coating layer 170 or even holes exposing the inner contents or permitting leakage of inner contents prematurely or unevenly. To reduce or eliminate agglomeration of particles or microparticles 144 in the reactor vessel 104 processing chamber 136, other processes require removal or manual disruption of particles or microparticles which can introduce contaminants or require manual or automatic physical cleaning of the inner walls of the vessel and the filters. As such, described herein is a reactor system 102 that does not require disassembly of the processing chamber 136 prior to completion of the ALD coating process. Instead, a complete ALD process can be run without intervention of the process in order to reduce, prevent, or disrupt the buildup of wall deposits and/or filter deposits and agglomeration.

While the agitator 106 (e.g., ultrasonic agitator) described herein transfers mechanical oscillations or vibrations to the processing chamber 136 by indirect or direct contact via the wave propagating structure 154, the agitator 106 can also transfer mechanical oscillations or vibrations to the processing chamber 136 via direct or indirect contact. For example, the agitator 106 can provide mechanical oscillations or vibrations through sonication such as an ultrasonic bath or jacket surrounding the processing chamber 136, or with an ultrasonic horn to transfer high-intensity sound waves through ambient air. In the case of including an ultrasonic bath or jacket, the agitator 106 can transfer the mechanical oscillations or vibrations to the reactor vessel through a fluid transfer medium. In some embodiments, ultrasonic baths such as ultrasonic cleaning baths can be used for transferring ultrasonic vibrations to a reactor system disclosed herein in order to reduce agglomeration and adhesion of particles or microparticles during a coating process. In certain embodiments, a reactor system disclosed herein can sit on a vibrating table or a table having an impactor, a vibrating motor, or both and the reactor system emersed in a medium, for example in an ultrasonic bath permitting the ultrasonic bath to ultrasonically agitate or vibrate the system and optionally, the table also transfers vibrations or impacts to a reaction chamber at the same or different time intervals and at lower frequencies. In some embodiments, a holding arm can be attached to the reactor system while suspended in a liquid-containing chamber having sonicating or agitation capabilities.

In some embodiments, as described in reference to FIG. 1, an impactor such as a pneumatic or solenoid hammer can be used to provide additional agitation. The impactor can be associated with, or coupled to, a part of the reactor vessel 104 (e.g., the processing chamber 136), or a structure that supports the reactor vessel 104, such as a table-top or other structure. As described in reference to FIG. 1, the impactor 188 (e.g., pneumatic hammer) is coupled to the reactor mount 180 such that, when actuated, the impactor 188 impacts the reactor mount 180, which transmits the vibration into the reactor vessel 104.

In some embodiments, as described in reference to FIG. 1, a vibrating motor 186 can be used to provide additional agitation. The vibrating motor 186 can be associated with, or coupled to, a part of the reactor vessel 104 (e.g., the processing chamber 136), or a structure that supports the reactor vessel 104, such as a table-top or other structure. The vibrating motor 186 (e.g., motor with offset weight) is coupled to the reactor mount 180 such that, when actuated, the motor 186 vibrates the reactor mount 180, which transmits the vibrations into the reactor vessel 104.

In some embodiments, the ultrasonic transducer of the agitator 106 can be in electrical communication with a controller that is configured to control the parameters of the delivery of ultrasound energy either directly or by remote control. The vibrating motor 186 and the impactor 188 can also be in electrical communication with the controller. In accordance with these embodiments, the controller can be configured to control the frequency, power, timing, and rate of delivery of ultrasound energy. In another embodiment, the controller can transfer mechanical oscillations to the reactor vessel 104 continuously or intermittently. The controller can be configured to transfer mechanical oscillations to the reactor vessel via the ultrasonic transducer at a frequency greater than 300 Hz (e.g., 10 or 20 KHzs, for example). In certain instances, the controller can be configured to transfer mechanical oscillations to the reactor vessel via the ultrasonic transducer at a frequency greater than 20,000 Hz. In some embodiments, the controller can be a computer that is programmed to operate and control the agitator.

In some embodiments, the interior surfaces of the chamber walls can include fins, baffles, imperfections, nodules, indentations and/or protrusions that increase the vibrational effect from the agitation. The mechanical oscillations or vibrations from the vibration motor or ultrasonic transducer to the interior structures can further deagglomerate or prevent agglomeration (e.g., disrupt agglomerates) of particles or microparticles that have or can become agglomerated to one another upon contacting the interior surfaces of the reactor vessel having the interior structures. In other embodiments, reactor systems disclosed herein can further include nodules or protrusions inside of the reactor housing the microparticle or particles to be coated to increase contact area of vibrating surfaces with bulk powder and aid in deagglomeration and in de-adherence from the walls and filters in the bulk phase. Such nodules or protrusions could be structures welded to the inside to the reactor.

Exemplary methods of using the reactor system described herein for reducing, preventing, or disrupting agglomeration and/or adherence when coating of microparticles can include the following non-limiting steps. Methods can include providing the reactor system 104 described herein including a reactor vessel 104 configured to permit a flow of process gas there through to coat a plurality of microparticles therein. The reactor vessel can include: an inlet at a first end of the reactor vessel; an outlet at a second end of the reactor vessel; one or more side walls within the reactor vessel and extending between the inlet and the outlet of the reactor vessel. The one or more sidewalls containing interior surfaces that define an internal volume. The reactor vessel can further include a processing chamber that is positioned between the inlet and the outlet of the reactor vessel. The processing chamber can include an inlet filter, an outlet filter, and chamber walls. The processing chamber can be configured to receive and retain the plurality of microparticles within the processing chamber to undergo a coating process in a fluidized bed environment. The reactor system can further include an agitator coupled to the reactor vessel and configured to deliver mechanical energy via sound waves to the reactor vessel to reduce the plurality of microparticles from at least one of agglomerating to one another and adhering to the chamber walls, the inlet filter, and the outlet filter. The agitator including a sonicator (e.g., ultrasonic transducer) configured to deliver mechanical energy, and a wave propagating structure coupled to the sonicator and the reactor vessel. The reactor can be mounted on a vibrating table or mount that can be further coupled to an impactor and a vibrating motor.

In other embodiments, methods can further include introducing the microparticles into the processing chamber of the reactor vessel. The microparticles can include at least one thermostable antigen or thermostable agent. The method can further include delivering a process gas into the processing chamber of the reactor vessel thereby generating a fluid bed for accepting the microparticles. The method can further include delivering mechanical energy (e.g., via sound waves) to the chamber walls of the processing chamber thereby reducing, preventing, or disrupting agglomeration of the microparticles to one another and adherence of the microparticles on the chamber walls, the inlet filter, and the outlet filter.

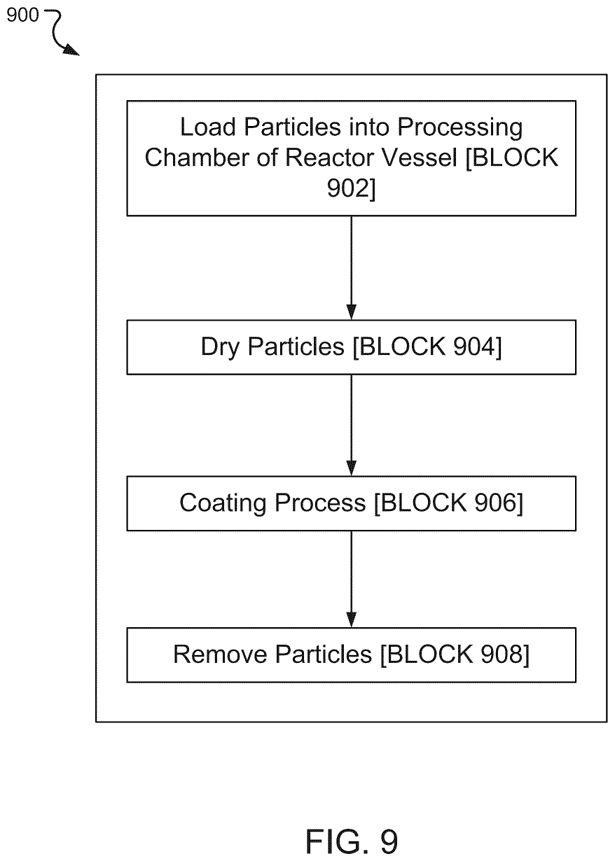

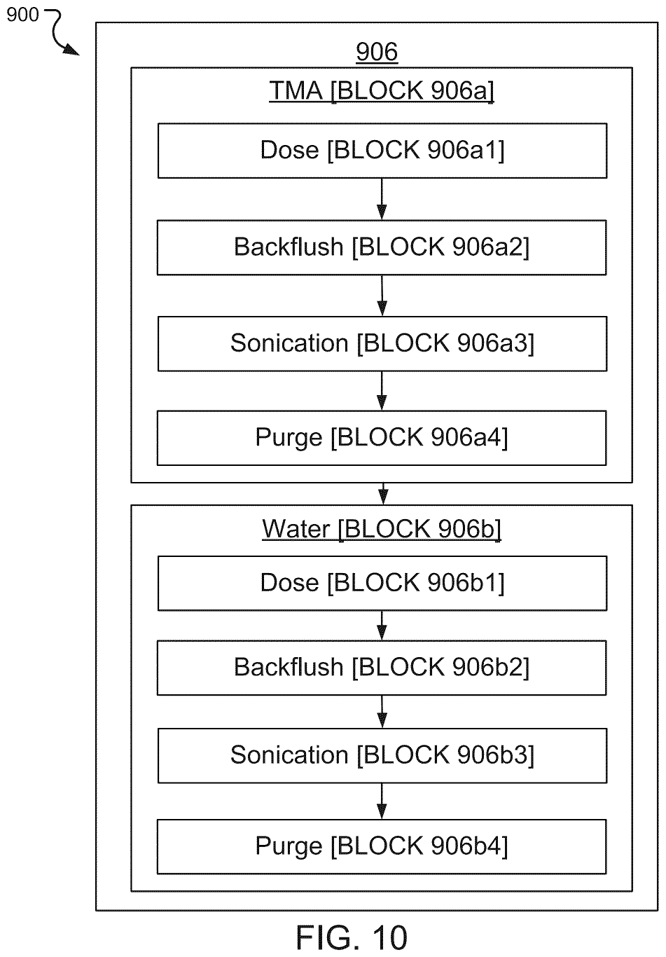

FIG. 9 is a flowchart illustrating an overview of a microparticle coating method 900. FIG. 10 is a flowchart illustrating some steps that can be associated with the coating process of the method 900 of FIG. 9, the coating process including the use of a fluidized bed and sonication (e.g., ultrasonic agitation) to reduce or prevent agglomeration and/or adherence of the particles or microparticles on the walls and filters of the processing chamber of the reactor vessel. The method 900 can be performed using the ALD system 100 of FIG. 1, and reference will be made to the various components of the system 100 while describing steps of the method 900.

FIG. 10 depicts the [Block 906] portion of the coating method 900. As illustrated in FIG. 9, the coating method 900 can include a step of loading the microparticles into the processing chamber 136 of the reactor vessel 104, at [Block 902]. This step can entail dispensing (or for example sieving) the microparticles into the processing chamber 136 between the inlet and outlet filters 140, 142, and securing the processing chamber 136 between the inlet section 130 and the outlet section 134 via the metal clamps 156. The microparticles can be of a size (diameter) between about 1 micron to about 10 microns. The sonicator 106 (e.g., ultrasonic agitator) can be coupled to the processing chamber 136 if it is not already coupled thereto. At [Block 904], the method 900 can include drying the particles within the processing chamber 136. This step can include delivering purge gas from the purge gas vessel 116 through the processing chamber 136 for a sufficient amount of time to dry the microparticles. In certain embodiments, purge gas can be delivered for one hour. In other embodiments, purge gas (e.g., argon) can be delivered for less than one hour. In certain instances, purge gas can be delivered for more than one hour. Once the microparticles are sufficiently dry or essentially dry, the coating processing of [Block 906] can be performed. The coating method 900 can additionally include a step of raising the temperature within the system and performing the coating process of [Block 906] at the elevated temperature. The temperature can be raised by having the reactor vessel 104 in a heated enclosure or an enclosure that maintains a uniformly elevated temperature of a desired range, the method 900 of FIG. 9. Within this block, there is a TMA section at [Block 906a] and a water section at [Block 906b]. Each section will be discussed in turn. The TMA section at [Block 906a], includes a dosing step at [Bock 906a1]. This step can include flowing purge gas from the purge gas vessel 116 into the conduit 123 with the valves 122d and 122a opened and the valves 122c, 122e closed. The valve 122e is then opened allowing the TMA to flow from the vessel 120 into the conduit 123 via the flow of purge gas. A regulating or needle valve 122j is used to adjust the flowrate of the TMA vessel. The TMA is delivered into the processing chamber 104 via the flow of purge gas. During this step, the seventh and eighth valves 122g, 122h can be opened and the ninth valve 122i can be closed. In certain instances, the TMA dosing step can last 0.6 minutes. During the dosing step, the microparticles are in a fluid bed created by the continuous flow of purge gas acting as a carrier gas for the TMA to flow through the reactor vessel 104.

Following the dosing step, the method can include but is not required to include a backflushing step illustrated at [Block 906a2]. In this optional step, any of the valves on the inlet side of the reactor vessel 104 are closed. The seventh and eight valves 122g, 122h on the outlet side of the reactor vessel 104 are also closed. The ninth valve 122i is opened so purge gas from the vessel 126 enters the conduit 123 and flows in an opposite direction through the reactor vessel 104 from the outlet opening 112 to the inlet opening 108. This backflushing aids in the dislodgement of buildup of microparticles or nanoparticles on the outlet filter 142 and the walls of the processing chamber 136. Backflushing of the system can cause some of the microparticles or nanoparticles to dislodge and fall back towards the inlet filter 140 (the reactor vessel 104 is vertically oriented so gravity causes the microparticles or nanoparticles to rest on the inlet filter 140). In certain embodiments, the backflushing or reversing the flow of the purge gas continues for a predetermined period such as about 0.015 minutes. In this example, the backflush can be a burst of purge gas that is delivered through the conduit 123 in reverse direction of flow from the rest of the process.

Following the backflushing step, the method can include sonication (e.g., ultrasonic agitation) at [Block 906a3]. This sonication process includes actuating the sonicator 106 (e.g., ultrasonic agitator) to deliver acoustic waves to the processing chamber 136 of the reactor vessel 104. The sonicator 106 can deliver acoustic waves to the processing chamber 136 at frequencies about 300 Hz to about 300 kHz; or about 10 kHz to 100 kHz; or alternatively about 20 kHz to about 50 kHz; alternatively, about 40 kHz. In certain instances, the sonication lasts for about 0.1 minutes or about 0.01 minute to about 1.0 minute. As described previously, the sonicator 106 is coupled directly to the processing chamber 136 and delivers acoustic waves to the walls of the processing chamber 136 to prevent agglomeration of the microparticles on the walls and filters thereof. During the sonication step, purge gas remains flowing through the reactor vessel 104 and provides a fluidized bed for the microparticles. It is noted that the sonication does not contribute to forming a fluidized bed within the reactor vessel 104; instead, the fluidized bed is provided by the delivery of process gas through the reactor vessel 104. In certain embodiments, sonication as disclosed herein can be modified such that purge gas is not flowed through the reactor vessel 104 during sonication. It is also noted that sonication as disclosed herein alleviates issues with agglomeration and/or adherence of the microparticles or nanoparticles during the coating process.

Following the sonication step, the method can include a purge step at [Block 906a4]. This step includes closing valves 122c and 122e while delivering purge gas into the conduit 123 from the vessel 116 to permit purge gas to flow (without TMA or water) through the reactor vessel 104 and out through the vacuum 124 (valves 122g, 122h being open, and valve 122i being closed). In certain embodiments, the purge step can last for 6 minutes.

Following the TMA process steps [Block 906a], the water process steps [Block 906b] are performed. The water process steps [Block 906b] begin with a dosing step [Block 906b1]. This step can include flowing purge gas from the purge gas vessel 116 into the conduit 123 with the valves 122c and 122e closed and valves 122a and 122d open. The valve 122c is then opened allowing the water vapor to flow from the vessel 118 into the conduit 123 via the flow of purge gas. A regulating or needle valve 122b is used to adjust the flow rate from the vessel 118. The water vapor is delivered into the processing chamber 104 via the flow of purge gas. During this step, the seventh and eighth valves 122g, 122h can be opened and the ninth valve 122i can be closed. In certain instances, the water vapor dosing step can last 0.8 minutes. During the dosing step, the microparticles are in a fluid bed created by the continuous flow of purge gas acting as a carrier gas for the water vapor to flow through the reactor vessel 104.

Following the dosing step, the method includes a backflushing step at [Block 906b2]. In this step, any of the valves on the inlet side of the reactor vessel 104 are closed. The seventh and eighth valves 122g, 122h on the outlet side of the reactor vessel 104 are also closed. The ninth valve 122i is opened so purge gas from the vessel 126 enters the conduit 123 and flows in an opposite direction through the reactor vessel 104 from the outlet opening 112 to the inlet opening 108. This backflushing aids in the dislodgement of buildup of microparticles or nanoparticles on the outlet filter 142 and the walls of the processing chamber 136. Some of the microparticles or nanoparticles are dislodged and fall back to the inlet filter 140 (the reactor vessel 104 is vertically oriented so gravity causes the microparticles or nanoparticles to rest on the inlet filter 140). In certain embodiments, the backflushing or flowing of the purge gas lasts for about 0.015 minutes. In essence the backflush is a burst of purge gas that is delivered through the conduit 123 in reverse direction of flow from the rest of the process.

Following the backflushing step, the method includes a sonication (e.g., ultrasonic agitation) step at [Block 906b3]. This step includes actuating the sonicator 106 (e.g., ultrasonic agitator) to deliver acoustic waves to the processing chamber 136 of the reactor vessel 104. The sonicator 106 can deliver acoustic waves to the processing chamber 136 at frequencies between about 300 Hz to about 300 kHz. In certain instances, the sonication lasts for about 0.1 minutes. As described earlier in this application, the sonicator 106 is coupled directly to the processing chamber 136 and delivers acoustic waves to the walls of the processing chamber 136 to prevent agglomeration of the microparticles on the walls and filters thereof. During the sonication step, purge gas remains flowing through the reactor vessel 104 and provides a fluidized bed for the microparticles. It is noted that the sonication does not contribute to forming a fluidized bed within the reactor vessel 104; instead, the fluidized bed is provided by the delivery of process gas through the reactor vessel 104. In certain embodiments, the sonication step can be modified such that purge gas is not flowed through the reactor vessel 104 during sonication.

Following the sonication step, the method includes a purge step at [Block 906b4]. This step includes closing valves 122e and 122c and opening the valves 122a and 122d while delivering purge gas into the conduit 123 from the vessel 116 to permit purge gas to flow (without TMA or water) through the reactor vessel 104 and out through the vacuum 124 (valves 122g, 122h being open, and valve 122i being closed). In other embodiments, the purge step can last for 6 minutes.

The steps of [Block 906] in FIG. 10 depict a single cycle of an ALD process, and the method can be repeated for a predetermined number of times to provide a suitable coating on the microparticle. For instance, the steps of [Block 906] in FIG. 10 can be performed five times or five cycles. Then, as seen in FIG. 9, the coating method 900 can next include removing the particles from the processing chamber [Block 908]. The coated nanoparticles or microparticles can be removed from the processing chamber for vialing and/or other container for use or storage. The nanoparticles or microparticles are not removed for purposes of disrupting agglomeration or adherence and then restarting the coating method. That is, at [BLOCK 908] of FIG. 9, the nanoparticles or microparticles are sufficiently coated and ready for vialing or container placement as being completely coated with a desired or predetermined number of coats. With the process provided by method 900 in FIGS. 9 and 10, the microparticles or nanoparticles have significantly reduced or are essentially free of agglomeration and adherence at the inlet and outlet filters 140, 142 and walls 138 of the chamber 136. Based on the processes disclosed herein, there is no need to remove partially coated microparticles or nanoparticles to sieve or even to scrape the walls 138 and filters 140, 142 during the coating process. In certain methods, one or more sieving steps at the beginning of the process can be used and/or a polishing step with an ultrasonically assisted sieve at the end can be utilized to remove the small fraction of remaining agglomerates that survive the final process if desired or that might have formed in reactor sections where agitation was insufficient to completely prevent powder deposition in the reactor chamber.

In certain embodiments, the coating process steps [Block 906] of FIGS. 9 and 10 additionally include operating the vibrating motor 186 and impactor 188. In other embodiments, the operation can be continuous. In accordance with these embodiments, the reactor vessel 104 is under continuous vibration via the vibrating motor 186 and periodic impaction via the impactor 188. In other embodiments, the operation can performed only during certain sub-steps of the method, such as during sonication (e.g., ultrasonic agitation) [Blocks 906a2 and 906b2].

As described in reference to FIGS. 9 and 10, delivering TMA and water vapor (separately) with a flow of purge gas provides a fluid bed within the reactor vessel 104. Fluidization of pharmaceutical powders with typical particles sizes between 1 and 10 micron and ALD coatings of these particle in a fluidized bed herein is accomplished by maintaining a constant purge gas flow through the inlet filter 140 during dosing phases that passes through the particle bed and is vented through the outlet filter into a vacuum line 124. The pressure in the processing chamber 136 is maintained between 1 and 10 torr at a gas velocity above the minimum fluidization velocity, typically in the range of 0.1-10 cm/s. Optimal fluidization gas velocity can be determined by visual observation of the bed behavior in a glass reactor or by measuring the pressure drop across the bed that increases until the minimum fluidization velocity is reached and then remains mostly constant. Constant low-frequency vibration (˜30 Hz) applied via the vibrational motor mounted to the reactor holder can aid fluidization during the dosing phase and minimizes channeling and bubble formation. During ALD coating process steps, the chemical precursors (TMA or water vapor) are sequentially added to the fluidization gas stream. During precursor dosing, the fluidization gas flow rate can be maintained or reduced to account for the additional precursor flow for a constant overall gas velocity.

### EXAMPLES

The materials, methods, and embodiments described herein are further defined in the following Examples. Certain embodiments are defined in the Examples herein. It should be understood that these Examples, while indicating certain embodiments, are given by way of illustration only. From the disclosure herein and these Examples, one skilled in the art can ascertain the essential characteristics of this invention, and without departing from the spirit and scope thereof, can make various changes and modifications of the invention to adapt it to various usages and conditions.

In one exemplary method, testing was performed on experimental powders using examples of the systems and methods described herein. First, experimental powders were obtained, as discussed below in the Example—Powder Sample Preparation section. In one set of examples, individual powder samples were used in various coating processes (e.g., number of ALD cycles, with and without sonication (e.g., ultrasonic agitation) but with continuous low-frequency bed vibration and intermittent impact). Photographic images were collected to illustrate the degree of agglomeration and reactor wall buildup and the particle size distribution showed the degree of agglomerates in the final product with and without intermittent ultrasonic agitation during the coating process. In a first example, ALD coating for 250 cycles was performed without sonication (as discussed below in Example 1). In a second example, ALD coating for was performed for 250 cycles with intermittent sonication (as discussed below in Example 2).

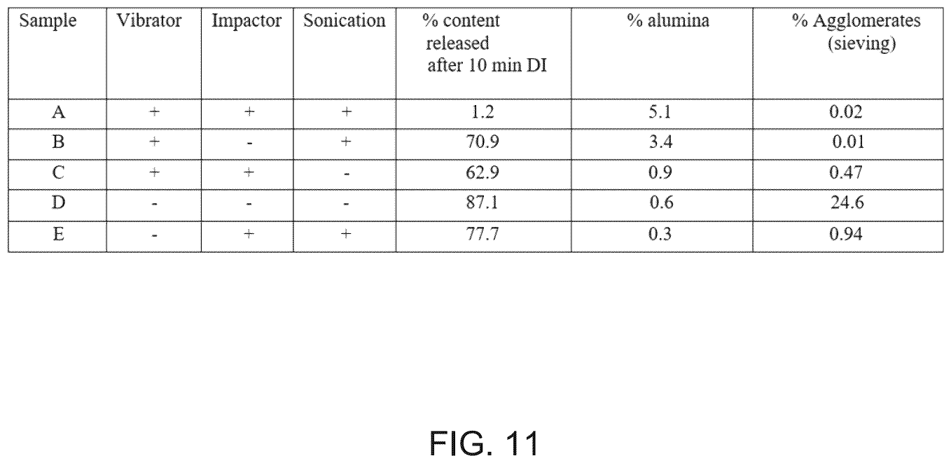

In another set of examples, individual powder samples were used in various coating processes (e.g., with and without vibration, with and without impactor, with and without sonication (e.g., ultrasonic agitation)), and various properties were analyzed (e.g., percent content released after 10 minutes in DI water, wt % alumina, wt % agglomerates after sieving). The properties of the powder samples as a function of the coating process are illustrated in the table in FIG. 11. In some examples, ALD coating was performed for 100 cycles without sonication (as discussed below in Example 3). In certain examples, ALD coating was performed for 100 cycles with intermittent sonication and with and without vibration and/or mechanical impact (as discussed below in Example 4). Additional testing was performed (as discussed below in Examples 5 and 6).

### Example—Powder Sample Preparation

Experimental powders were obtained. In these example methods, powders with a composition of approximately 70-90 wt % trehalose, 10-25 wt % hydroxyethlystarch, and 5-10 wt % other minor components were prepared by spray drying (e.g., with a Bucchi B-290 Mini Spray Dryer (Buchi Labortechnik AG, Flawil, Switzerland) fitted with a two-fluid nozzle at an inlet temperature of 60-100° C. for the drying gas, an outlet temperature of 40-60° C., and an atomizer flow rate of 5-10 liters/minute for the spray nozzle). The powders were further dried in a lyophilizer FTS Systems Lyophilizer, Warminster, PA) at 60 mTorr for 16 h at 40° C. to a residual moisture content of less than 1% as determined by Karl-Fischer titration.

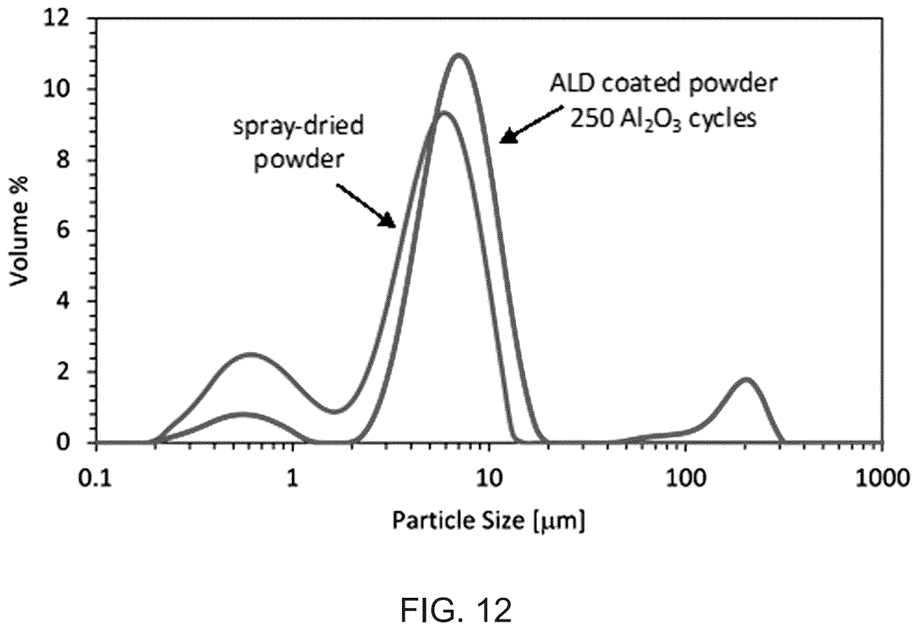

The particle size distribution was measured with a Malvern Analytical Mastersizer 2000 laser particle size analyzer (Malvern, UK). The line labeled “spray-dried powder” in FIG. 12 illustrates that the particle sizes of the spray dried sample have bimodal distribution with a small fraction of sub-micron particles and an average size of a majority of particles near 6 μm. The BET surface area of approximately 1 m²/g was consistent with the size distribution. FIG. 12 is a representative chart illustrating particle size distribution of spray dried powder both before and after coating with 250 alumina ALD cycles that did not include sonication after each precursor dose (average of 3 measurements).

Example 1-ALD Coating without Agitation (e.g., without Ultrasonic Agitation)

In one example, a powder sample (e.g., prepared as described in the Example Powder Sample Preparation section, above, approximately 3 grams) was coated with 250 alumina ALD cycles. The powder sample was added to an ALD reactor chamber with an inner diameter of 3.5 cm and a length of 5 cm, equipped with 10 μm sintered stainless steel filter discs at both the inlet and outlet. The system was evacuated to a pressure of less than 3 torr with a mechanical vacuum pump and constant Argon purge of approximately 3 cm³/min (STP) was initiated to fluidize and mix the powder. Additionally, a constant 27 Hz vibration was applied with a vibration motor attached to the reactor mounting table to aid the fluidization.

In one experiment, the temperature was increased to 50° C. over a one-hour period for further drying and the powder was then coated with 250 cycles of alumina ALD at 50° C. Both trimethylaluminum and water were dosed sequentially with intermittent purging to remove unreacted precursors. The dosing times were in the range of 0.5 to 1 minute and purge times ranged from 3-7 minutes. After each dose, the reactor was briefly vented from the outlet side through an automated valve with a burst of dry Argon, followed by re-evacuation, to minimize filter deposits and to aid mixing. In this example, after venting, 3-5 impacts were applied with a pneumatic impactor to further remove any wall or filter deposits. After about 100 cycles, the reactor was vented, deposits on the walls and filter were scraped off and the bulk powder was agitated and stirred manually with a spatula for about 1-2 minutes to deagglomerate and break up any visible clumps without removing the powder from the chamber, and the coating process was continued. The overall coating duration was about 48 hours. After completion of the ALD process, a sample of the powder was calcined at 850° C. in air to remove the organic particle core and determine the alumina content from the mass of the residual. The sample contained 12 wt % of alumina, consistent with previously reported coatings carried out at similar conditions.

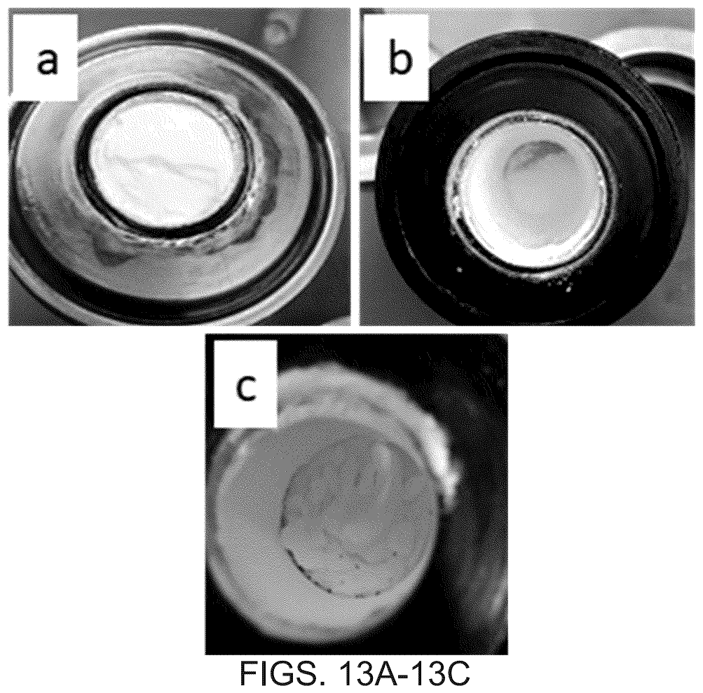

In one exemplary method, after approximately 100 alumina ALD cycles, thick deposits of particles were visible on both the outlet filter (as illustrated in FIG. 13A, which is a photograph of some buildup on outlet filter after approximately 100 alumina ALD cycles) and the reactor walls (as illustrated in FIG. 13B, which is a photograph of reactor content after approximately 100 alumina ALD cycles), indicating that mechanical impact, low-frequency vibration, and gas fluidization were not sufficient to avoid buildup on the reactor surfaces. Even intermittent deagglomeration and removal of wall deposits (e.g., as described above after 100 cycles) did not prevent further buildup after restarting the coating process. Significant deposits were frequently observed after only 10-20 cycles, independent of the number of cycles that were previously applied.

In another example, after approximately 250 alumina ALD cycles, chunks of particles that are often visible in loose reactor content (as illustrated in FIG. 13C, which is a photograph of typical reactor content after 250 alumina ALD cycles) were likely formed by filter buildup that eventually dislodged during the coating process. These are problematic and can cause significant product loss and reduce uniform coating of particles, for example. After collecting the powder, including scraping off the buildup from the filters without any further milling, the particle size distribution was measured with the particle size analyzer to determine the fraction of agglomerates. The line labeled “ALD coated powder, 250 Al₂O₃ cycles” in FIG. 12 illustrates that compared to the starting material (e.g., the sample powder, as illustrated by the line labeled “spray-dried powder”), the amount of sub-micron particles decreased, and the main peak shifted slightly to larger diameters, likely due to the permanent attachment of the sub-micron particles to the larger particles or formation of sub-micron particle agglomerates. In addition, a significant fraction of particles larger than 40 μm were detected. This fraction potentially underestimates the total fraction of agglomerates in the final product since the powders are aerosolized in a bed of vibrating metal spheres for the size measurements with the particle size analyzer and this process likely deagglomerates some of the larger agglomerates. In addition, scaping the layers off the reactor walls and filters also redisperses agglomerates but does not address the underlying issues and inconsistencies of the coating process introduced by these adverse effects.

Fractions of larger agglomerates was also estimated by using an ultrasonic sifting device with sieve openings (e.g., 43 μm). Even though the sieve opening size is much larger than the primary particle size, due to the adhesiveness of the powders, only particles with a size distribution similar to the primary particles were collected after a few minutes of sieving. The weight fraction of the residual coarse material ranged from 10-30%. Extended sieving times (e.g., greater than 30 minutes) eventually deagglomerated the coarse material into primary particles but this is an inefficient process and deagglomeration using a sieve can introduce holes into particles.

Example 2-ALD Coating, 250 Cycles with Intermittent Agitation (e.g., with Intermittent Ultrasonic Agitation)

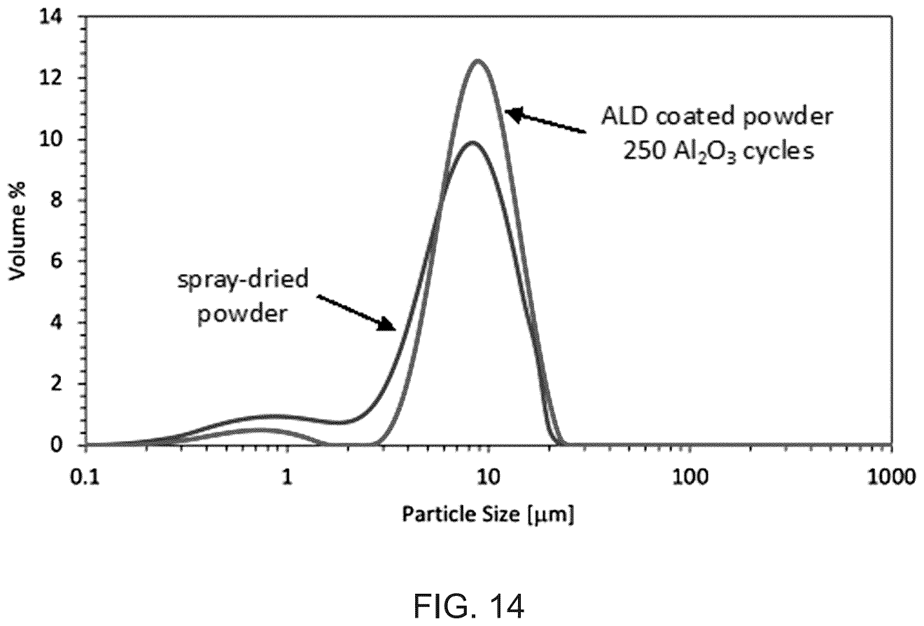

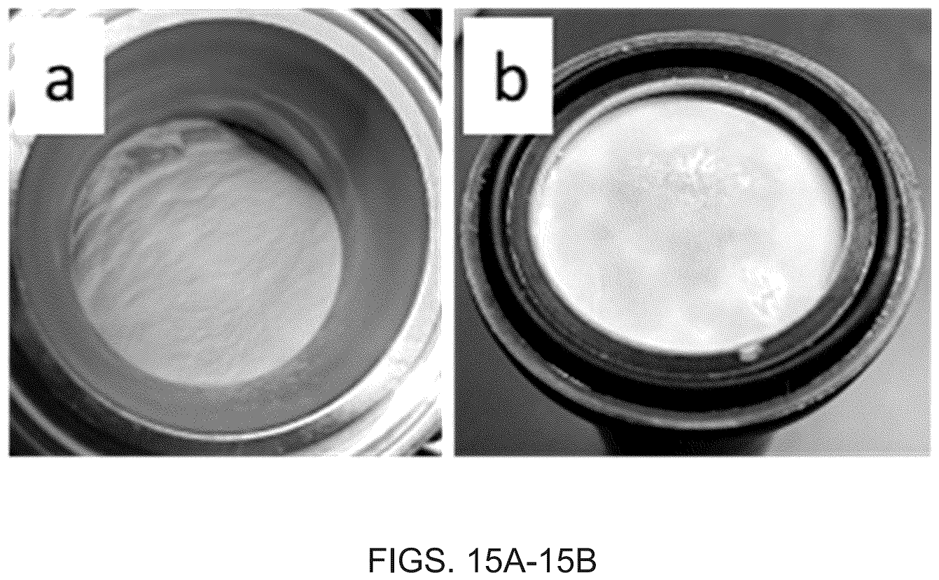

In another exemplary method, a powder sample (e.g., prepared as described in the Example Powder Sample Preparation section, above) was coated with 250 uninterrupted alumina ALD cycles. All procedural steps described in Example 1 (above) were used, except intermittent manual deagglomeration and scraping was not used as it was inefficient and can introduce contaminants etc. as disclosed herein. In addition, an ultrasonic transducer attached directly to the ALD reaction chamber was activated for 6 seconds at the same time as the mechanical impactor was activated. FIG. 14 is a chart illustrating particle size distribution of spray dried powder before and after coating with 250 alumina ALD cycles that included sonication (e.g., ultrasonic agitation) after each precursor dose (average of 3 measurements). FIG. 15A is an exemplary photographic image illustrating typical reactor content after 250 uninterrupted alumina ALD cycles with intermittent sonication (e.g., ultrasonic agitation) and FIG. 15B is an exemplary photographic image illustrating typical buildup on outlet filter after 250 uninterrupted alumina ALD cycles with intermittent sonication (e.g., ultrasonic agitation).

FIG. 15A illustrates the reactor walls and FIG. 15B illustrates the outlet filter after 250 uninterrupted alumina ALD cycles with the intermittent ultrasonic vibration of the reactor walls. No buildup was observed except for a very thin coating that may be partially due to some chemical vapor depositon (CVD) because of an incomplete purge instead of attached particles. No scraping of the walls of the reactor chamber or the filters were required to collect greater than 95% of the coated powder. A very small fraction of coarse agglomerates (e.g., less than 5%) was apparent only after sieving the powder for about 2-3 minutes. The significantly reduced concentration of agglomerates that were detected by sieving might have been dispersed by the aerosolization process (e.g., Mastersizer) and thus were not detected in the size distribution.

Example 3-ALD Coatings, without Sonication (e.g., without Ultrasonic Agitation)

In another exemplary experiment, samples (e.g., albumin) were prepared (2-3 g each) similarly to Example 1 except that 100 alumina ALD layers were deposited. The quality of the coatings was assessed by suspending approximately 100 mg of the coated material into approximately 1.5 ml of DI water for 10 minutes at ambient temperature. The concentration of the particle core formulation that dissolved due to defects in the coating was measured gravimetrically. A solution was separated from the particle residues by centrifuging, the water was evaporated to dryness at 100° C. and the weight of the residue indicated the fraction of content dissolved from defective particles (wt % of soluble particle core-content released [%] for example, see Table in FIG. 11). The alumina loading due to the ALD layers was obtained gravimetrically after calcining the particle residue at 850° C. to remove all organic material.

The table in FIG. 11 illustrates properties of samples as function of coating process for 100 cycles of ALD coating. The table in FIG. 11 illustrates that in some cases, it is difficult for precursors to reach all surfaces without all measures-without vibrator, without impactor, and without sonicator (e.g., without ultrasonic agitator)-leaving low alumina contents. In one exemplary method, the vibrator included a low frequency vibration accomplished with a vibration table, impact with an automated hammer, and high frequency vibration with a sonicator. In certain example, a vibration motor (3200 rpm) can include a McMaster vibration motor. In other examples or in combinations a pneumatic impactor can include a PKL 190/4, Martin Vibration impactor for example.

Sample C in the table in FIG. 11, for example, illustrates that more than 50% of the particle content was released from the coated particles in few minutes for a sample where the reactor was under constant low frequency vibration, a mechanical impactor was actuated for several seconds, and a brief backflush was initiated after each precursor exposure. Sample D in the table in FIG. 11, for example, illustrates that without any mechanical agitation applied during the coatings, and the only means for fluidization supplied by the flow of process gases, nearly 90% of the coated contents was released in 10 minutes and alumina loadings were low. In addition, the final product contained large quantities of agglomerates as measured by sieving the coated powder after removal from the reactor, which are further justification for the need for agitation during these coating processes.

Example 4-ALD Coatings, 100 Cycles with Intermittent Sonication (e.g., Intermittent Ultrasonic Agitation) with and without Vibration and/or Impact

In another exemplary experiment, particles prepared with the sonication device were also suspended in DI water for approximately 10 minutes, as described in Example 5 (above). Sample A in the table in FIG. 11, for example, illustrates that only about 1% of the content dissolved and about 5 wt % alumina was deposited by the alumina coatings when all agitation methods (vibration, impactor, and sonication (e.g., ultrasonic agitation) were applied. Sample B and Sample E in the table in FIG. 11, for example, illustrate that when one of vibration or impact was omitted while maintaining intermittent sonication, the wall deposits were avoided but the fraction of defective particles was large. Similarly, the alumina loading decreased, likely because all mechanical agitation methods were necessary to maintain sufficient fluidization in the bulk powder volume and even exposure to the ALD precursors. The coating quality will likely depend on the strength and frequency of the vibration applied to the reactor as well as by the frequency, intensity, and duration of the impactor and sonication device. In certain examples, an ultrasonic system (transducer and control board) can include a UEACC system or other model.

Example 5-In Vitro Release Profile of ALD Coating, Coatings Applied with Intermittent Sonication (e.g., Intermittent Ultrasonic Agitation)

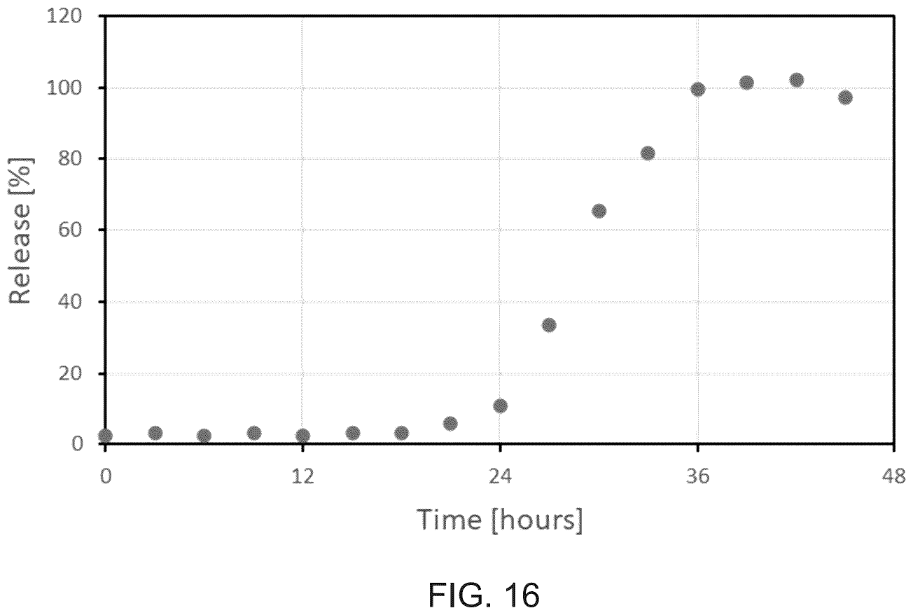

In another exemplary experiment, delayed step release of contents of coated particles or microparticles in aqueous liquids was measured under constant agitation. Ovalbumin was incorporated in the particle core, coatings were carried out according to Example 4 with all mechanical agitators utilized in this example, and the protein concentration released was determined using a standard BCA protein assay in regular intervals over several days until steady state was reached. FIG. 16 is a graph illustrating the content (ovalbumin) release of the content coated at elevated temperature with 100 ALD layers of Al₂O₃ in a buffer. Very little release of the contents was observed within 24 hours. After about 24 to 28 hours some release occurred with about 100 percent release observed at about 36 hours after incubation. Thus, the particles maintain their contents for up to about 24 hours in this buffer without release.

Example 6-Excessive Agitation without Additional Coating.

In another exemplary experiment, it was observed that fully coated particles generated using agitation processes disclosed herein of use in methods disclosed herein can be further subjected to agitation by a reactor system disclosed herein for several hours to over one day (data not shown). For example, pharmaceutical agents contained within fully coated particles previously subjected to methods of agitation disclosed herein and then subjected to agitation without further coating in a reactor system disclosed herein remain intact for at least 8 hours or at least 24 hours and in certain cases over 40 hours. In certain cases, this agitation can be constant for a predetermined period and in other cases this agitation can be intermittent for a predetermined period and the sequestered pharmaceutical content remained intact for exposures of up to about 20 or up to about 40 hours of additional agitation without further coating of the particles. These samples were tested for release of sequestered agent(s) in a buffer after exposure to these disclosed conditions. It is noted that coated particles, however, may be damaged by additional agitation of 8 hours or more without concurrent layer deposition if the coating is not sufficiently thick or the number of coatings is few and these coatings are not mechanically robust prior to the additional agitation in absence of coating, as observed by a large fraction of the particles with only a few coatings prematurely releasing their content in buffer solutions. Therefore, in certain embodiments, additional agitation without coating can be used as needed and can be used for up to 8 hours or up to 40 hours depending on the coating condition of the particles where sufficient coating is needed to withstand prolonged reactor system agitation without additional coating; for example, greater than 8 hours when the coating layers are few.

All the compositions and methods disclosed and claimed herein can be made and executed without undue experimentation in light of the present disclosure. While the compositions and methods have been described in terms of embodiments, it is apparent to those of skill in the art that variations can be applied to the compositions and methods and in the steps or in the sequence of steps of the methods described herein without departing from the concept, spirit and scope herein. More specifically, certain agents that are both chemically and physiologically related can be substituted for the agents described herein while the same or similar results would be achieved. All such similar substitutes and modifications apparent to those skilled in the art are deemed to be within the spirit, scope and concept as defined by the appended claims.

What is claimed is:

1. A reactor system for coating a plurality of particles, the reactor system comprising:
a reactor vessel configured to house the plurality of particles therein and configured to permit a flow of process gas there through to coat the plurality of particles, the reactor vessel comprising:
an inlet at a first end of the reactor vessel;
an outlet at a second end of the reactor vessel;
one or more side walls extending between the inlet and the outlet of the reactor vessel, the one or more side walls comprising an interior surface that defines an internal volume;
a processing chamber within the reactor vessel positioned between the inlet and the outlet of the reactor vessel, the processing chamber including an inlet filter, an outlet filter, and chamber walls, the processing chamber configured to receive and retain the plurality of particles within the processing chamber to undergo a coating process in a fluidized bed environment; and
one or more agitator(s) associated with or coupled to the reactor vessel and configured to deliver mechanical energy to the reactor vessel to reduce the plurality of particles from at least one of agglomerating to one another and adhering to the chamber walls, adhering to the inlet filter, and adhering to the outlet filter, the one or more agitator(s) comprising a sonicator configured to deliver mechanical energy, and a wave propagating structure coupled to the sonicator and the reactor vessel.

2. The reactor system according to claim 1, wherein the wave propagating structure comprises a shaft collar, the shaft collar extending around at least a portion of the reactor vessel.

3. The reactor system according to claim 2, wherein the one or more side walls of the processing chamber define a cylindrical tube, cone, cube or other configuration, the shaft collar secured to the cylindrical tube, cone, cube, or other configuration of the processing chamber.

4. The reactor system according to claim 3, wherein the shaft collar is releasably secured to the cylindrical tube of the reactor vessel.

5. The reactor system according to claim 1, wherein the wave propagating structure comprises a threaded member coupled to the sonicator and the reactor vessel.

6. The reactor system according to claim 1, wherein the sonicator comprises an ultrasonic transducer and an electrical wave or high-frequency electrical wave generator in electrical communication with the ultrasonic transducer, the electrical wave or high-frequency electrical wave generator configured to generate oscillating electrical energy such that the ultrasonic transducer delivers ultrasound energy to the wave propagating structure.

7. The reactor system according to claim 1, wherein the sonicator is configured to continuously, or intermittently, or at a particular time in a coating process, deliver the mechanical energy from the one or more agitator(s) to the reactor vessel.

8. The reactor system according to claim 1, wherein the reactor vessel is configured to introduce the process gas according to vapor phase coating techniques including atomic layer deposition (ALD), chemical vapor deposition (CVD), molecular layer deposition (MLD), or physical vapor deposition (PVD).

9. The reactor system according to claim 1, wherein the plurality of particles to be coated comprise at least one antigen or at least one agent.

10. The reactor system according to claim 1, wherein the at least one antigen comprises at least one thermostable antigen or at least one thermostable agent.

11. The reactor system according to claim 1, further comprising at least one of 1) an impactor coupled to the reactor vessel and 2) an impactor coupled to a supporting surface which supports or stabilizes the reactor vessel, and the impactor configured to impact the reactor vessel to reduce the plurality of particles from at least one of agglomerating to one another, adhering to the chamber walls, adhering to the inlet filter, and adhering to the outlet filter.

12. (canceled)

13. The reactor system according to claim 11, wherein the impactor is a pneumatic hammer, or a solenoid hammer configured to impact the reactor vessel within a frequency range of about 0.5 Hz to about 10 Hz.

14. The reactor system according to claim 1, wherein interior of the chamber walls of the processing chamber include at least one protrusion or indentation extending inwardly, at least one nodule or protrusion extending outwardly or combinations thereof.

15. An atomic layer deposition (ALD) system comprising the reactor system according to claim 1.

16. A method for reducing, preventing, or disrupting at least one of agglomeration and adherence of particles when coating a plurality of particles, the method comprising:
providing the reactor system according to claim 1 for reducing, preventing, or disrupting at least one of agglomeration and adherence when coating particles;
introducing the plurality of particles into the processing chamber of the reactor vessel, the plurality of particles comprising at least one thermostable antigen, thermostable compound, or thermostable agent;
delivering a process gas into the processing chamber of the reactor vessel and generating a fluidized bed for the plurality of particles;
delivering mechanical energy to chamber walls of the processing chamber and reducing, preventing, or disrupting at least one of agglomeration, adherence of the particles to one another, adherence to the chamber walls, adherence to the inlet filter, and adherence to the outlet filter.

17. The method according to claim 16, wherein the one or more agitator(s) is configured to deliver mechanical energy to the reactor vessel at frequencies between 300 Hz and 300 kHz; alternatively about 10 kHz to 100 kHz; or alternatively about 20 kHz to about 50 kHz; alternatively about 40 kHz.

18. (canceled)

19. The method according to claim 16, further comprising impacting the reactor vessel or a structure coupled to the reactor vessel with an impactor to aid in reducing, preventing, or disrupting at least one of agglomeration, adherence of the particles on the chamber walls, adherence on the inlet filter, and adherence on the outlet filter.

20-26. (canceled)

27. The method according to claim 16, wherein the reactor vessel is not opened for dislodgement of agglomerated or adhered particles on the chamber walls of the processing chamber of the reactor vessel during the coating process.

28. The method according to claim 16, wherein the reactor vessel is not opened until the coating process of the plurality of particles is complete.

29. A kit comprising:
the reactor system according to claim 1; and
instructions for using the reactor system.

30-45. (canceled)
